(19) United States
(12) Patent Application Publication
(10) Pub. No.: US 2024/0047433 A1
(43) Pub. Date: Feb. 8, 2024

(54) SEMICONDUCTOR DEVICE

(71) Applicant: ROHM CO., LTD., Kyoto-shi (JP)

(72) Inventors: Xiaopeng WU, Kyoto-shi (JP); Kohei TANIKAWA, Kyoto-shi (JP)

(21) Appl. No.: 18/491,355

(22) Filed: Oct. 20, 2023

Related U.S. Application Data
(63) Continuation of application No. PCT/JP2022/022584, filed on Jun. 3, 2022.

(30) Foreign Application Priority Data
Jun. 15, 2021 (JP) 2021-099537

(51) Int. Cl. H01L 25/07; H01L 23/00; H01L 23/498; H01L 23/31

(52) U.S. Cl. CPC H01L 25/072; H01L 24/32; H01L 23/49811; H01L 24/40; H01L 23/49844; H01L 23/3107; H01L 2224/32245; H01L 2224/40175

(57) ABSTRACT

A semiconductor device includes a conductive substrate, first semiconductor elements bonded to the substrate, a first terminal on a side in first direction relative to the substrate, and a conductor (first/second wirings) connected to the semiconductor elements and the terminal. The first wiring includes a first end connected to the terminal and a second end separated from the first end in first direction. The second wiring is connected to the first wiring between the first and second ends. The first wiring includes first and second parts. The first part is between the first end and a connecting portion (first connecting part) at which the second wiring is connected to the first wiring. The second part is between the first connecting part and the second end. In a direction crossing the flow direction of the main circuit current, the first part has a larger size than the second part.

### TECHNICAL FIELD

The present disclosure relates to a semiconductor device.

### BACKGROUND ART

Semiconductor devices with power switching elements such as MOSFETs (Metal Oxide Semiconductor Field Effect Transistors) or IGBTs (Insulated Gate Bipolar Transistors) are conventionally known. These semiconductor devices are used in a variety of electronic equipment, including industrial equipment, home appliances, information terminals, and automotive equipment. A conventional semiconductor device (power module) is disclosed in JP-A-2015-220382. The semiconductor device disclosed in JP-A-2015-220382 includes a semiconductor element and a support substrate (ceramic substrate). The semiconductor element is, for example, an IGBT made of Si (silicon). The support substrate supports the semiconductor element. The support substrate includes an insulating base and conductive layers provided on opposite sides of the base. The base is made of ceramic, for example. The conductive layers are made of Cu (copper), for example. The semiconductor element is bonded to one of the conductive layers.

### BRIEF DESCRIPTION OF THE DRAWINGS

FIG. 1 is a perspective view of a semiconductor device according to a first embodiment of the present disclosure.

FIG. 2 is a perspective view corresponding to FIG. 1, from which a sealing resin is omitted.

FIG. 3 is a perspective view corresponding to FIG. 2, from which a first conductive member is omitted.

FIG. 4 is a plan view of the semiconductor device shown in FIG. 1.

FIG. 5 is a plan view corresponding to FIG. 4, in which the sealing resin is indicated by imaginary lines.

FIG. 6 is a right side view of the semiconductor device shown in FIG. 1, in which the sealing resin is indicated by imaginary lines.

FIG. 7 is a left side view of the semiconductor device shown in FIG. 1, in which the sealing resin is indicated by imaginary lines.

FIG. 8 is a partial enlarged view of FIG. 5, from which the sealing resin is omitted.

FIG. 9 is a plan view of the first conductive member, in which a first extension and a second extension are developed.

FIG. 10 is a plan view corresponding to FIG. 5, in which the sealing resin and the first conductive member are omitted, and a second conductive member is indicated by imaginary lines.

FIG. 11 is a right side view of the semiconductor device shown in FIG. 1.

FIG. 12 is a bottom view of the semiconductor device shown in FIG. 1.

FIG. 13 is a sectional view taken along line XIII-XIII in FIG. 5.

FIG. 14 is a sectional view taken along line XIV-XIV in FIG. 5.

FIG. 15 is a partial enlarged view of FIG. 14.

FIG. 16 is a partial enlarged view of FIG. 14.

FIG. 17 is a sectional view taken along line XVII-XVII in FIG. 5.

FIG. 18 is a sectional view taken along line XVIII-XVIII in FIG. 5.

FIG. 19 is a sectional view taken along line XIX-XIX in FIG. 5.

FIG. 20 is a sectional view taken along line XX-XX in FIG. 5.

FIG. 21 is a plan view corresponding to FIG. 8 (with the sealing resin omitted) showing a semiconductor device according to a first variation of the first embodiment.

FIG. 22 is a plan view corresponding to FIG. 8 (with the sealing resin omitted) showing a semiconductor device according to a second variation of the first embodiment.

FIG. 23 is a plan view corresponding to FIG. 5, showing a semiconductor device according to a third variation of the first embodiment.

### DETAILED DESCRIPTION OF EMBODIMENTS

The following describes preferred embodiments of the present disclosure with reference to the drawings.

In the present disclosure, the terms such as “first”, “second”, and “third” are used merely as labels and are not intended to impose ordinal requirements on the items to which these terms refer.

In the present disclosure, the phrases “an object A is formed in an object B” and “an object A is formed on an object B” include, unless otherwise specified, “an object A is formed directly in/on the object B” and “an object A is formed in/on the object B with another object interposed between the object A and the object B”. Similarly, the phrases “an object A is disposed in an object B” and “an object A is disposed on an object B” include, unless otherwise specified, “an object A is disposed directly in/on the object B” and “an object A is disposed in/on the object B with another object interposed between the object A and the object B”. Similarly, the phrase “an object A is located on an object B” includes, unless otherwise specified, “an object A is located on an object B in contact with the object B” and “an object A is located an object B with another object interposed between the object A and the object B”. Also, the phrase “an object A overlaps with an object B as viewed in a certain direction” includes, unless otherwise specified, “an object A overlaps with the entirety of an object B” and “an object A overlaps with a portion of an object B”.

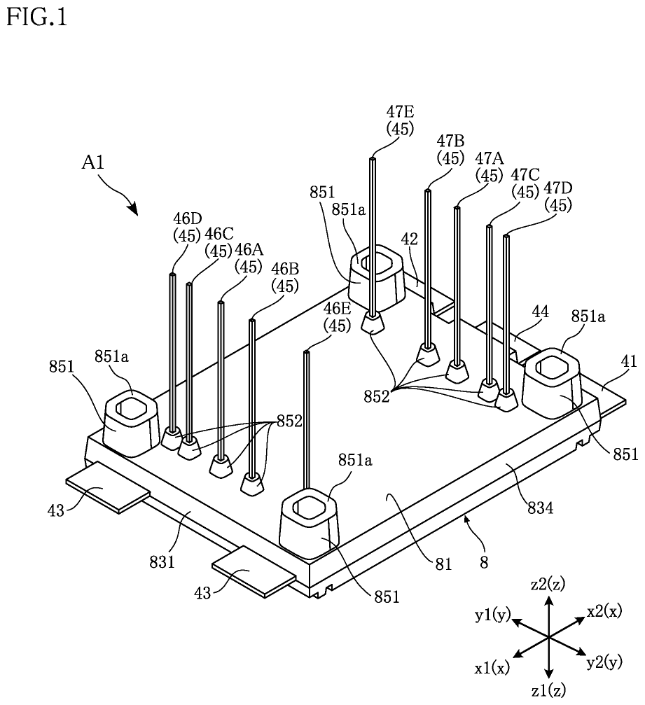

FIGS. 1 to 20 show a semiconductor device according to a first embodiment of the present disclosure. The semiconductor device A1 of the present embodiment includes a plurality of first semiconductor elements 10A, a plurality of second semiconductor elements 10B, a conductive substrate 2, a support substrate 3, a first terminal 41, a second terminal 42, a plurality of third terminals 43, a fourth terminal 44, a plurality of control terminals 45, a control terminal support 48, a first conductive member 5, a second conductive member 6 and a sealing resin 8.

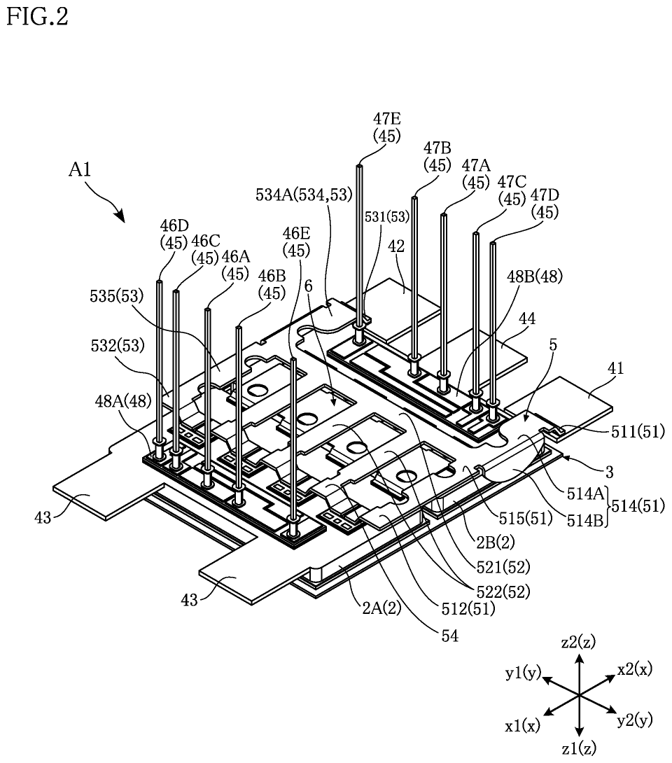

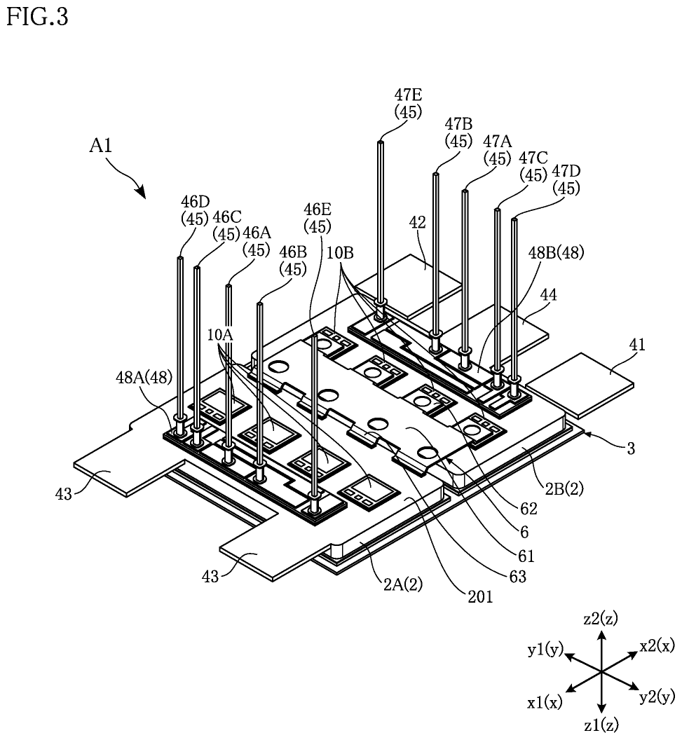

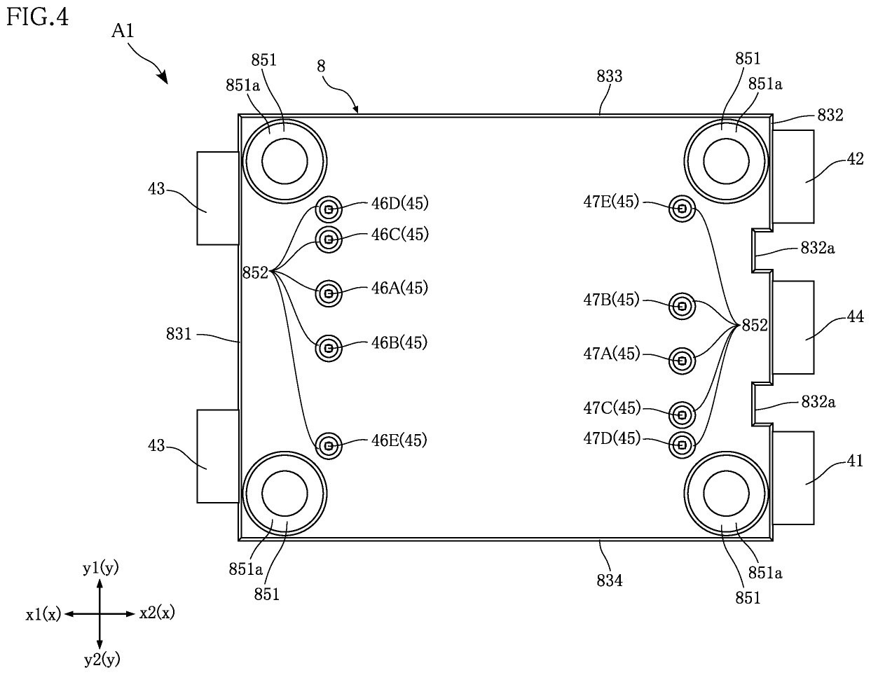

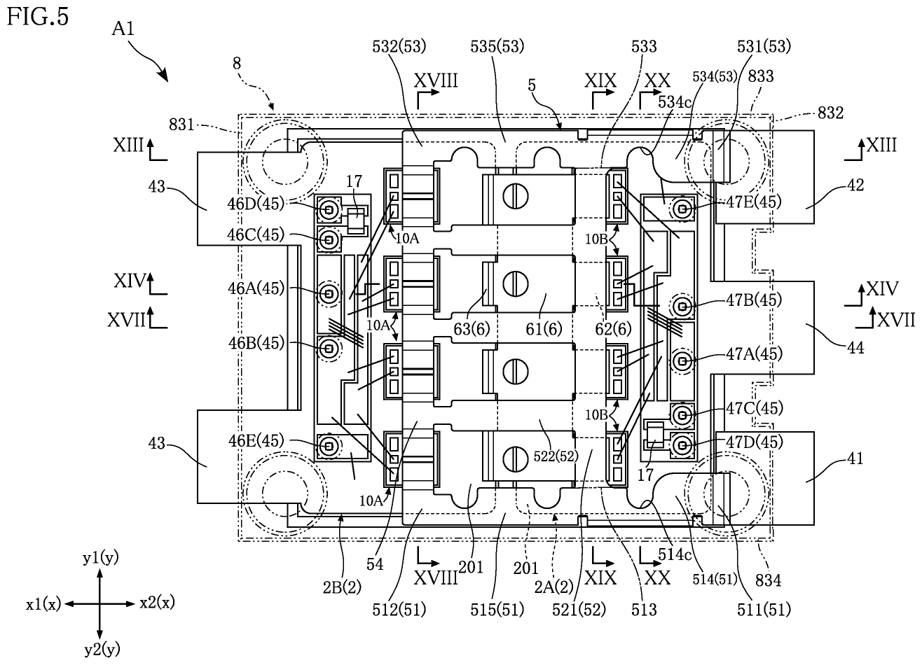

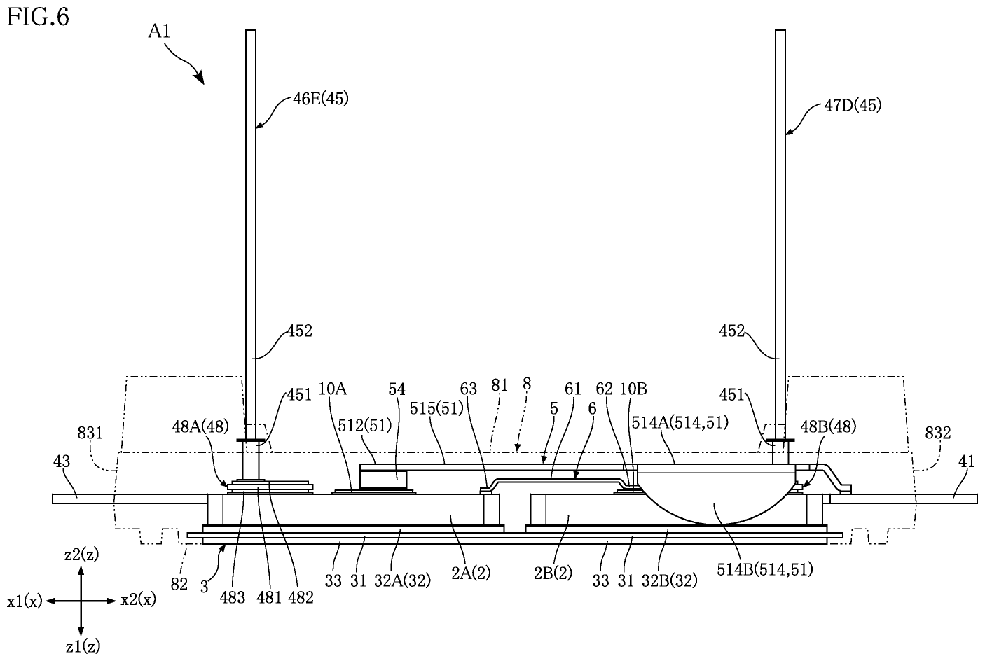

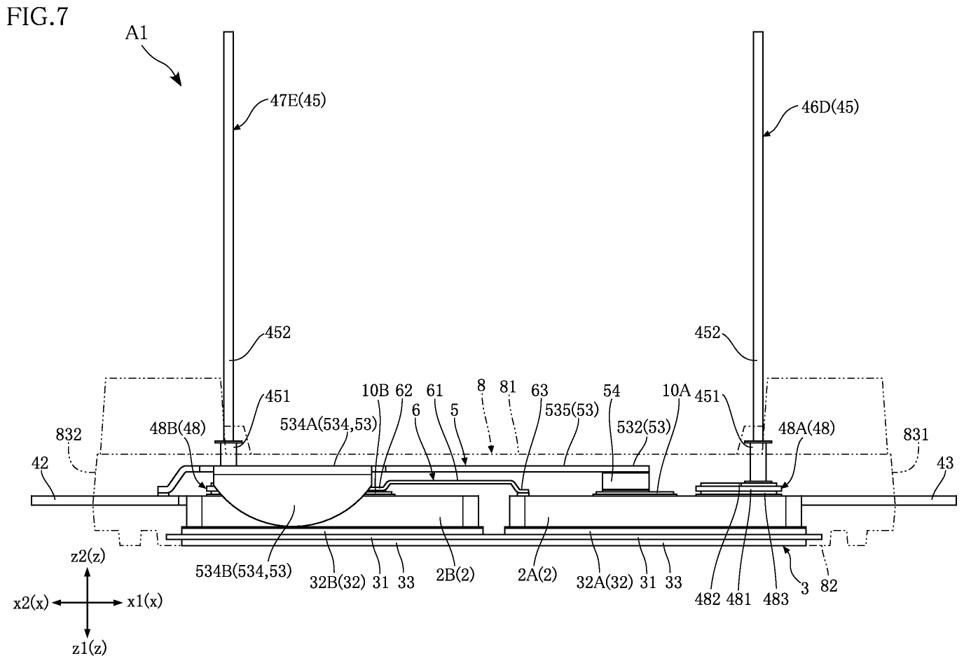

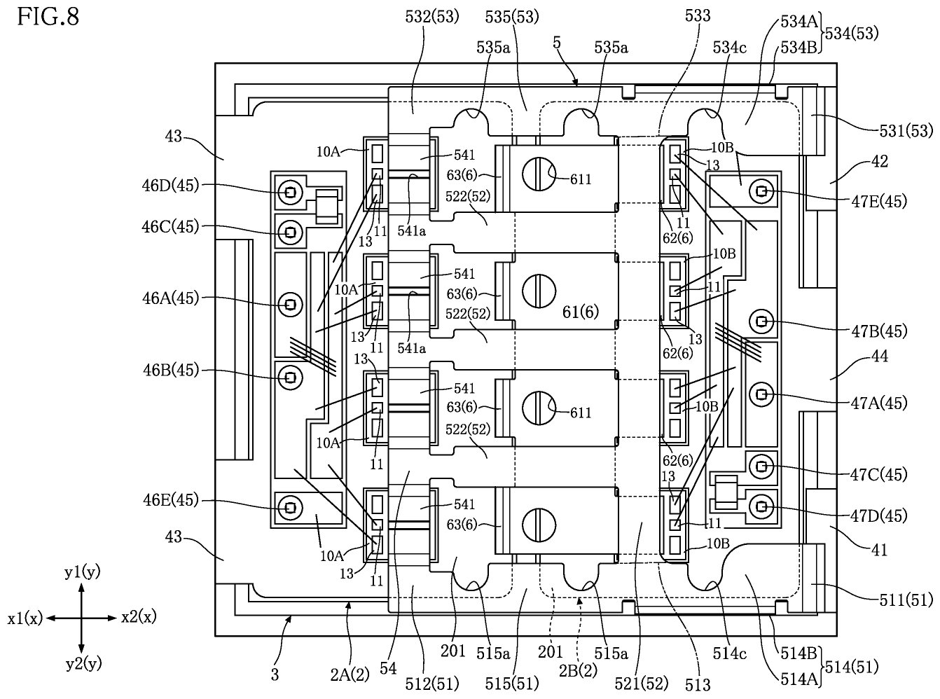

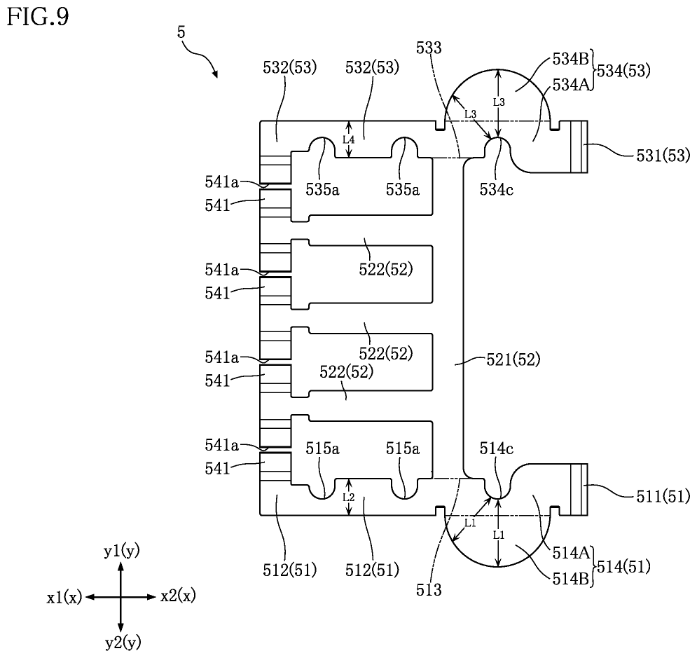

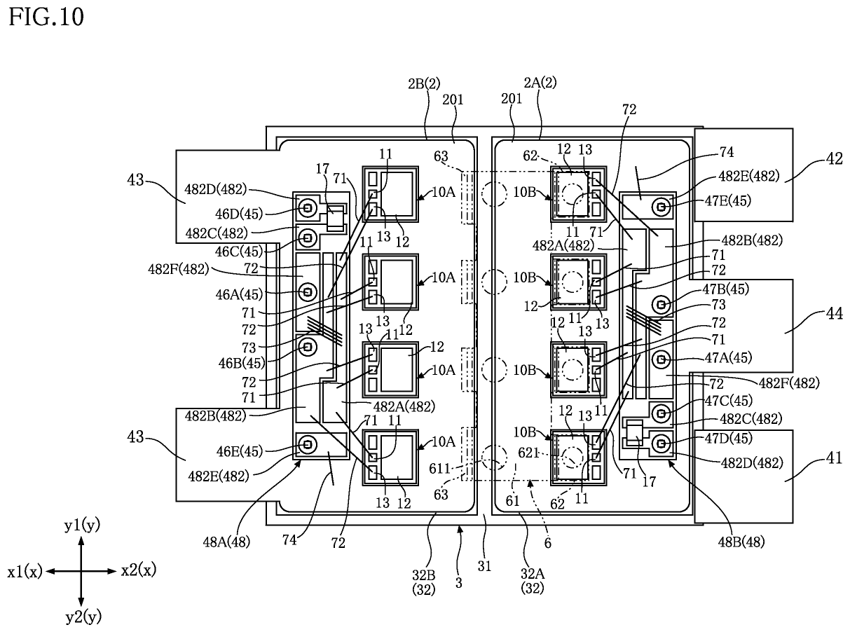

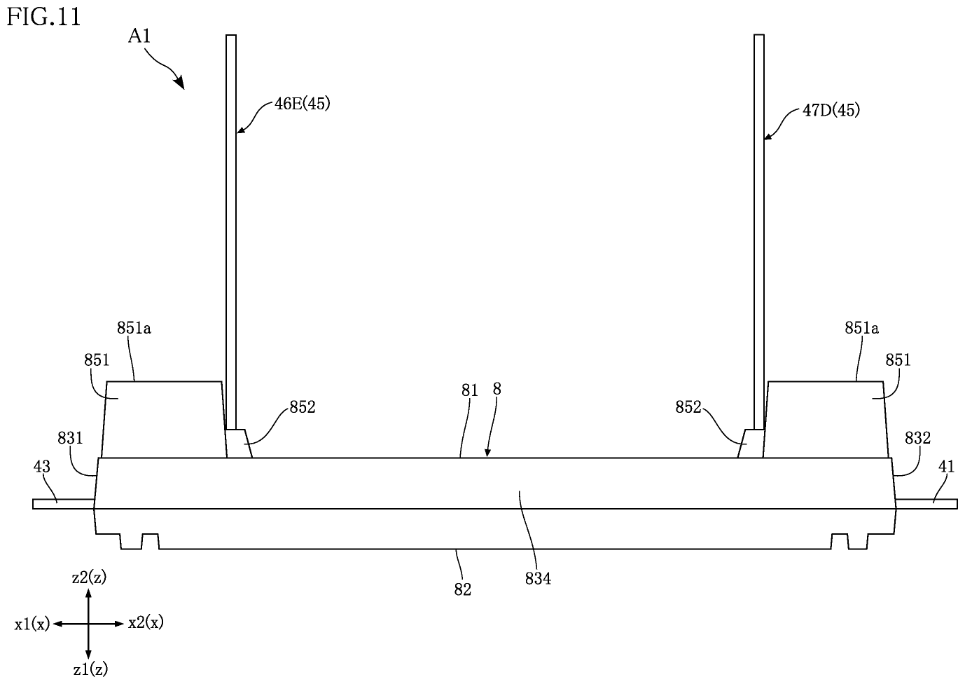

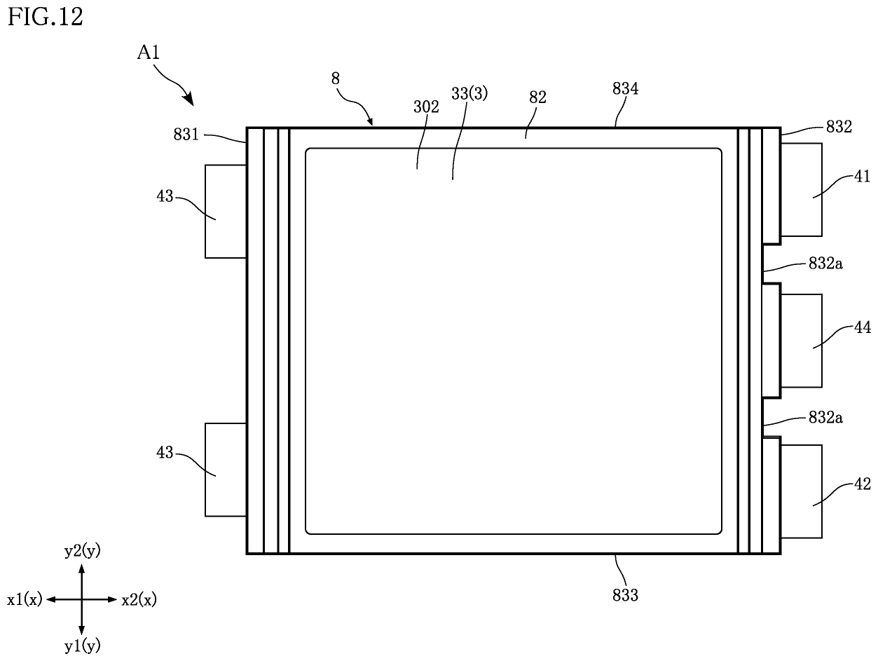

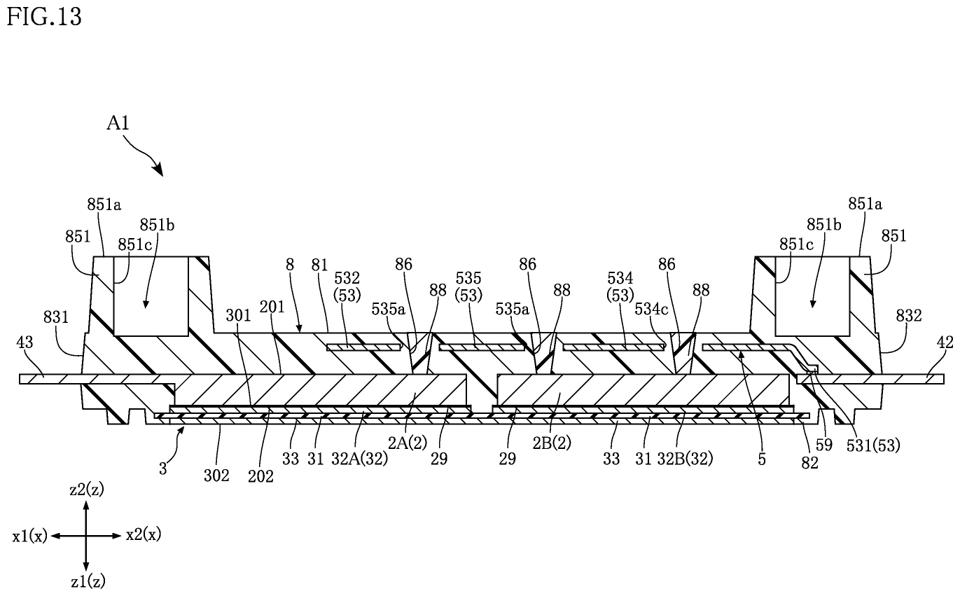

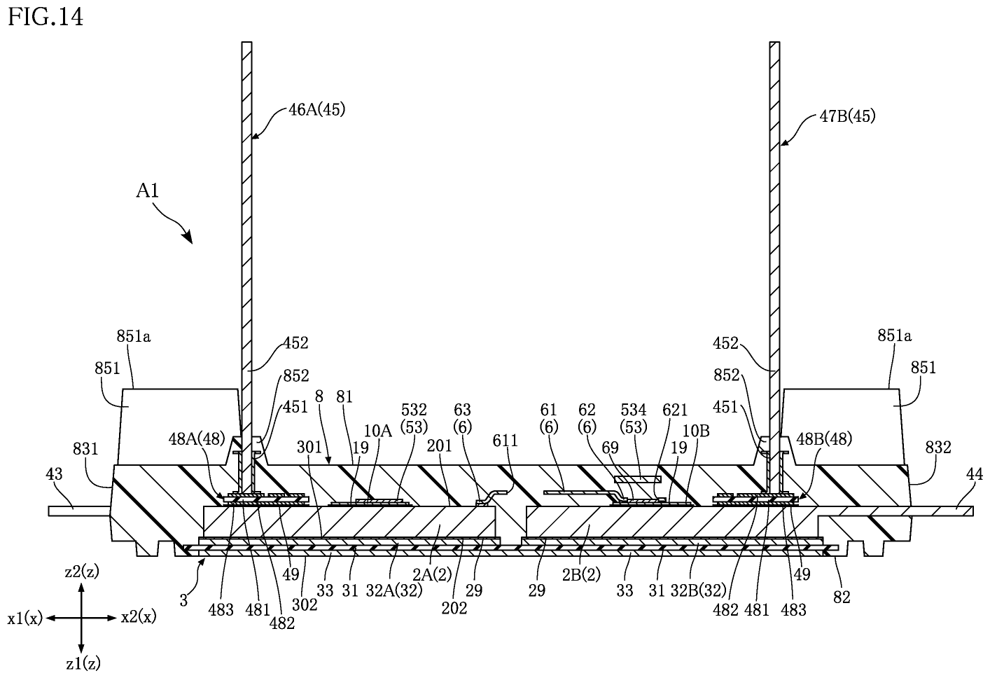

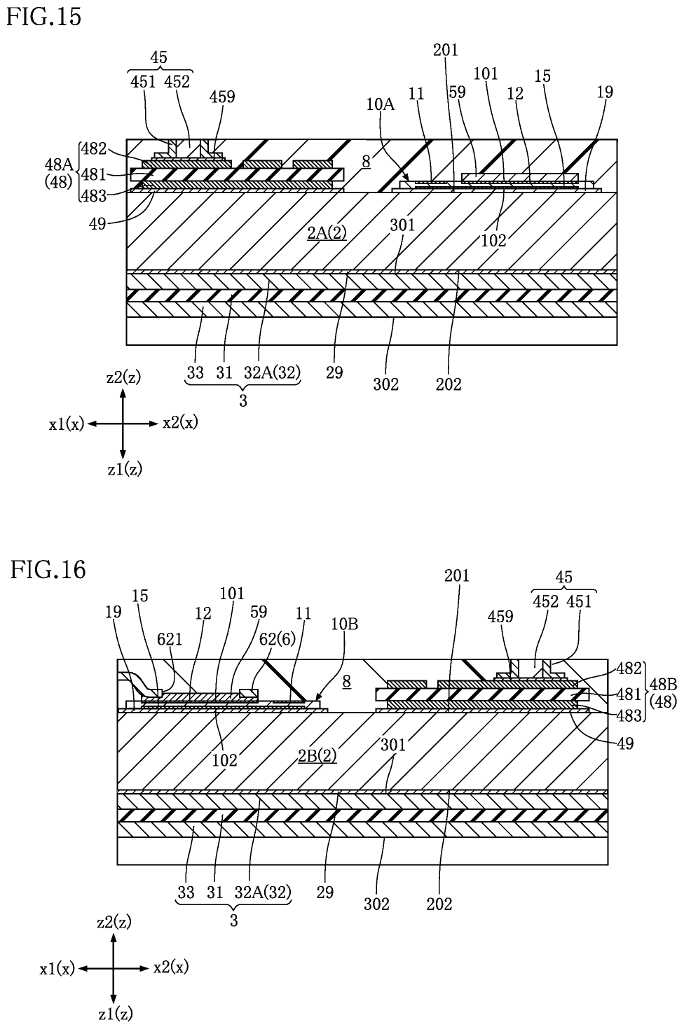

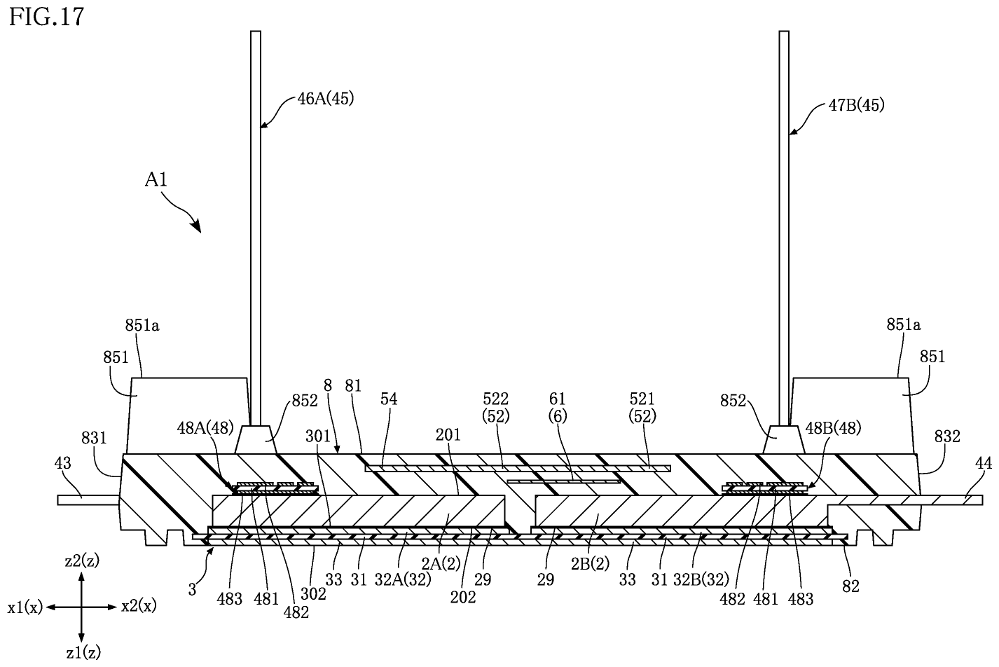

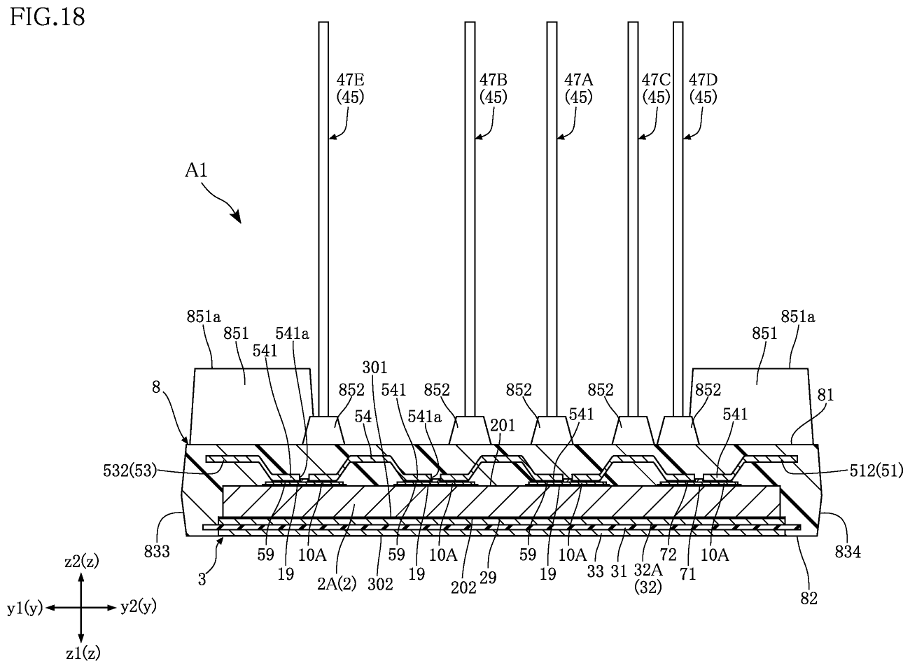

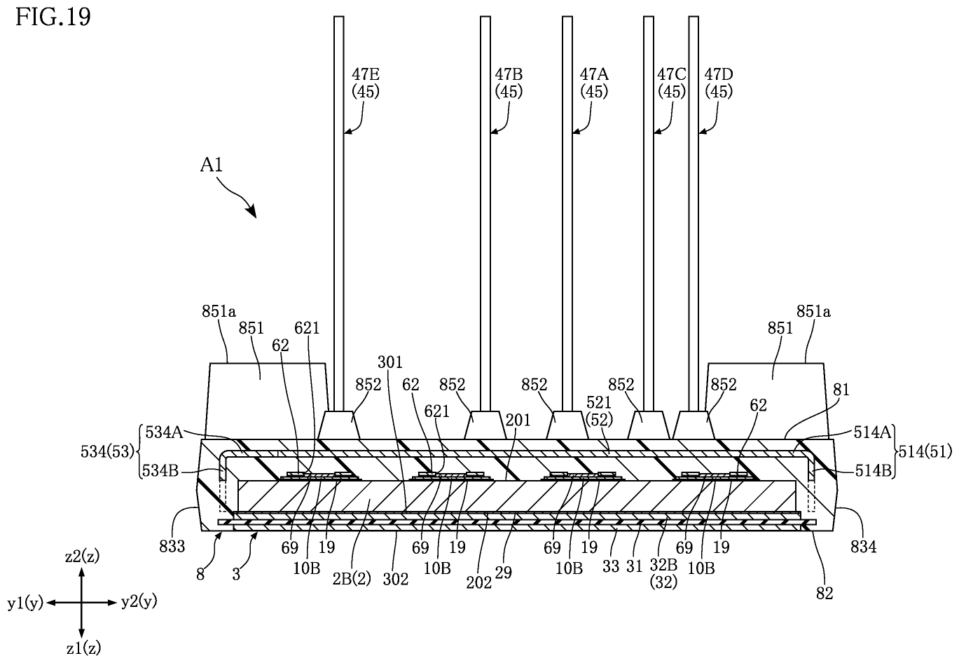

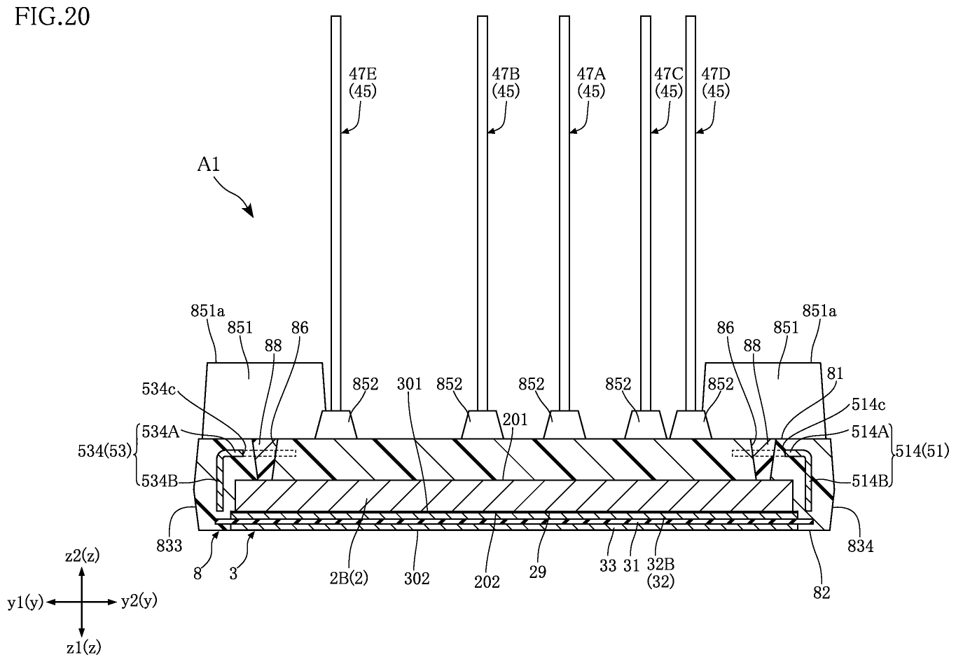

FIG. 1 is a perspective view of a semiconductor device A1. FIG. 2 is a perspective view corresponding to FIG. 1, from which the sealing resin 8 is omitted. FIG. 3 is a perspective view corresponding to FIG. 2, from which the first conductive member 5 is omitted. FIG. 4 is a plan view of the semiconductor device A1. FIG. 5 is a plan view corresponding to FIG. 4, in which the sealing resin 8 is indicated by imaginary lines. FIG. 6 is a right side view of the semiconductor device A1, in which the sealing resin 8 is indicated by imaginary lines. FIG. 7 is a left side view of the semiconductor device A1, in which the sealing resin 8 is indicated by imaginary lines. FIG. 8 is a partial enlarged view of FIG. 5, from which the sealing resin 8 is omitted. FIG. 9 is a plan view of the first conductive member 5, in which a first extension 514B and a second extension 534B, described later, are developed. FIG. 10 is a plan view corresponding to FIG. 5, in which the sealing resin 8 and the first conductive member 5 are omitted and the second conductive member 6 is indicated by imaginary lines. FIG. 11 is a right side view of the semiconductor device A1. FIG. 12 is a bottom view of the semiconductor device A1. FIG. 13 is a sectional view taken along line XIII-XIII in FIG. 5. FIG. 14 is a sectional view taken along line XIV-XIV in FIG. 5. FIGS. 15 and 16 are partial enlarged views of FIG. 14. FIG. 17 is a sectional view taken along line XVII-XVII in FIG. 5. FIG. 18 is a sectional view taken along line XVIII-XVIII in FIG. 5. FIG. 19 is a sectional view taken along line XIX-XIX in FIG. 5. FIG. 20 is a sectional view taken along line XX-XX in FIG. 5.

For the convenience of description, three mutually orthogonal directions are defined as an x direction, a y direction, and a z direction. The z direction is, for example, the thickness direction of the semiconductor device A1. The x direction is the horizontal direction in a plan view (see FIG. 4) of the semiconductor device A1. The y direction is the vertical direction in a plan view (see FIG. 4) of the semiconductor device A1. In the description below, “in plan view” means as viewed in the z direction.

Each of the first semiconductor elements 10A and the second semiconductor elements 10B is an electronic component as a core for the function of the semiconductor device A1. The constituent material of the first semiconductor elements 10A and the second semiconductor elements 10B is, for example, a semiconductor material mainly composed of SiC (silicon carbide). The semiconductor material is not limited to SiC and may be Si (silicon), GaN (gallium nitride) or C (diamond). Each of the first semiconductor elements 10A and the second semiconductor elements 10B is a power semiconductor chip having a switching function, such as a MOSFET (Metal Oxide Semiconductor Field Effect Transistor). The first semiconductor elements 10A and the second semiconductor elements 10B are MOSFETs in the present embodiment, but are not limited to these and may be other transistors such as IGBTs (Insulated Gate Bipolar Transistors). The first semiconductor elements 10A and the second semiconductor elements 10B are all identical with each other. Each of the first semiconductor elements 10A and the second semiconductor elements 10B is, for example, an n-channel MOSFET, but may be a p-channel MOSFET.

As shown in FIGS. 15 and 16, each of the first semiconductor elements 10A and the second semiconductor elements has an element obverse surface 101 and an element reverse surface 102. In each of the first semiconductor elements 10A and the second semiconductor elements 10B, the element obverse surface 101 and the element reverse surface 102 are spaced apart from each other in the z direction. The element obverse surface 101 faces in the z2 direction, and the element reverse surface 102 faces in the z1 direction.

In the present embodiment, the semiconductor device A1 includes four first semiconductor elements 10A and four second semiconductor elements 10B. The number of first semiconductor elements 10A and the number of second semiconductor elements 10B are not limited to this configuration, and may be may be changed as appropriate in accordance with the performance required of the semiconductor device A1. In the example shown in FIG. 10, four each of the first semiconductor elements 10A and the second semiconductor elements 10B are provided. The number of first semiconductor elements 10A and the number of second semiconductor elements 10B may be two, three, or five or more. The number of first semiconductor elements 10A and the number of second semiconductor elements 10B may be the same or may be different. The number of first semiconductor elements 10A and the number of second semiconductor elements 10B are determined based on the current capacity of the semiconductor device A1.

The semiconductor device A1 may be configured as a half-bridge type switching circuit. In this case, in the semiconductor device A1, the second semiconductor elements 10B constitute the upper arm circuit, and the first semiconductor elements 10A constitute the lower arm circuit. In the upper arm circuit, the second semiconductor elements 10B are connected in parallel with each other. In the lower arm circuit, the first semiconductor elements 10A are connected in parallel with each other. Each second semiconductor element 10B and a relevant one of the first semiconductor elements 10A are connected in series to form a bridge layer.

As shown in FIGS. 10, 18, etc., each of the first semiconductor elements 10A is mounted on the conductive substrate 2. In the example shown in FIG. 10, the first semiconductor elements 10A may be aligned in the y direction and are spaced apart from each other. Each of the first semiconductor elements 10A is conductively bonded to the conductive substrate 2 (the first conductive portion 2A, described later) via a conductive bonding material 19. With the first semiconductor elements 10A bonded to the first conductive portion 2A, the element reverse surfaces 102 face the first conductive portion 2A.

As shown in FIGS. 10, 19, etc., each of the second semiconductor elements 10B is mounted on the conductive substrate 2. In the example shown in FIG. 10, the second semiconductor elements 10B may be aligned in the y direction and are spaced apart from each other. Each of the second semiconductor elements 10B is conductively bonded to the conductive substrate 2 (the second conductive portion 2B, described later) via a conductive bonding material 19. With the second semiconductor elements 10B bonded to the second conductive portion 2B, the element reverse surfaces 102 face the second conductive portion 2B. As will be understood from FIG. 10, the first semiconductor elements 10A and the second semiconductor elements 10B overlap with each other as viewed in the x direction, but may not overlap with each other.

Each of the first semiconductor elements 10A and the second semiconductor elements 10B has a first obverse electrode 11, a second obverse electrode 12, a third obverse electrode 13, and a reverse electrode 15. The configurations of the first obverse electrode 11, the second obverse electrode 12, the third obverse electrode 13 and the reverse electrode 15 described below are common to the first semiconductor elements 10A and the second semiconductor elements 10B. The first obverse electrode 11, the second obverse electrode 12 and the third obverse electrode 13 are provided on the element obverse surface 101. The first obverse electrode 11, the second obverse electrode 12 and the third obverse electrode 13 are insulated from each other by an insulating film, not shown. The reverse electrode 15 is provided on the element reverse surface 102.

The first obverse electrode 11 is, for example, a gate electrode, through which a drive signal (e.g., gate voltage) for driving the first semiconductor element 10A (the second semiconductor element 10B) is input. In each first semiconductor element 10A (each second semiconductor element 10B), the second obverse electrode 12 is, for example, a source electrode, through which source current flows. The third obverse electrode 13 is, for example, a source sense electrode, through which source current flows. The reverse electrode 15 is, for example, a drain electrode, through which drain current flows. The reverse electrode 15 covers the entire (or almost entire) element reverse surface 102. The reverse electrode 15 is formed by Ag (silver) plating, for example.

Each of the first semiconductor elements 10A (the second semiconductor elements 10B) switches between a conducting state and a disconnected state in response to a drive signal (gate voltage) inputted to the first obverse electrode 11 (the gate electrode). In the conducting state, a current flows from the reverse electrode 15 (the drain electrode) to the second obverse electrode 12 (the source electrode). In the disconnected state, this current does not flow. That is, each first semiconductor element 10A (each second semiconductor element 10B) performs a switching operation. The semiconductor device A1 use the switching function of the first semiconductor elements 10A and the second semiconductor elements 10B to convert the DC voltage inputted between the single fourth terminal 44 and the two, i.e., the first and the second terminals 41 and 42 into e.g. AC voltage and outputs the AC voltage from the third terminal 43.

As shown in FIGS. 5, 10, etc., the semiconductor device A1 includes thermistors 17. The thermistors 17 are used as a temperature detection sensor.

The conductive substrate 2 supports the first semiconductor elements 10A and the second semiconductor elements 10B. The conductive substrate 2 is bonded on the support substrate 3 via a conductive bonding material 29. The conductive substrate 2 is, for example, rectangular in plan view. The conductive substrate 2, together with the first conductive member 5 and the second conductive member 6, constitutes a path for the main circuit current switched by the first semiconductor elements 10A and the second semiconductor elements 10B.

The conductive substrate 2 includes a first conductive portion 2A and a second conductive portion 2B. Each of the first conductive portion 2A and the second conductive portion 2B is a plate made of a metal. The metal may be Cu (copper) or a copper alloy, for example. The first conductive portion 2A and the second conductive portion 2B, together with the first terminal 41, the second terminal 42, the third terminals 43 and the fourth terminal 44, constitute a conduction path to the first semiconductor elements 10A and the second semiconductor elements 10B. As shown in FIGS. 13 to 20, each of the first conductive portion 2A and the second conductive portion 2B is bonded on the support substrate 3 via a conductive bonding material 29. Each of the first semiconductor elements 10A is bonded to the first conductive portion 2A via a conductive bonding material 19. Each of the second semiconductor elements 10B is bonded to the second conductive portion 2B via a conductive bonding material 19. The constituent material of the conductive bonding materials 19 and the conductive bonding materials 29 is not particularly limited, and may be solder, metal paste or sintered metal, for example. As shown in FIGS. 3, 10, 13 and 14, the first conductive portion 2A and the second conductive portion 2B are spaced apart from each other in the x direction. In the example shown in these figures, the first conductive portion 2A is located on the x1 side of the second conductive portion 2B. Each of the first conductive portion 2A and the second conductive portion 2B is, for example, rectangular in plan view. The first conductive portion 2A and the second conductive portion 2B overlap with each other as viewed in the x direction. Each of the first conductive portion 2A and the second conductive portion 2B has dimensions of, for example, 15 mm to 25 mm in the x direction, 30 mm to 40 mm in the y direction, and 1.0 mm to 5.0 mm (preferably, about 2.0 mm) in the z direction.

The conductive substrate 2 has an obverse surface 201 and a reverse surface 202. As shown in FIGS. 13, 14 and 17 to 20, the obverse surface 201 and the reverse surface 202 are spaced apart from each other in the z direction. The obverse surface 201 faces in the z2 direction, and the reverse surface 202 faces in the z1 direction. The obverse surface 201 is constituted of the upper surface of the first conductive portion 2A and the upper surface of the second conductive portion 2B. The reverse surface 202 is constituted of the lower surface of the first conductive portion 2A and the lower surface of the second conductive portion 2B. The reverse surface 202 is bonded to the support substrate 3 such that it faces the support substrate 3.

The support substrate supports the conductive substrate 2. The support substrate 3 is provided by an AMB (Active Metal Brazing) substrate. The support substrate 3 includes an insulating layer 31, a first metal layer 32, and a second metal layer 33.

The insulating layer 31 may be ceramics having excellent thermal conductivity, for example. Examples of such ceramics include SiN (silicon nitride). The insulating layer 31 is not limited to ceramics and may be a sheet of insulating resin, for example. The insulating layer 31 is, for example, rectangular in plan view.

The first metal layer 32 is formed on the upper surface (the surface facing in the z2 direction) of the insulating layer 31. The constituent material of the first metal layer 32 includes Cu, for example. The constituent material may include A1 (aluminum) rather than Cu. The first metal layer 32 includes a first portion 32A and a second portion 32B. The first portion 32A and the second portion 32B are spaced apart from each other in the x direction. The first portion 32A is located on the x1 side of the second portion 32B. The first conductive portion 2A is bonded to and supported by the first portion 32A. The second conductive portion 2B is bonded to and supported by the second portion 32B. Each of the first portion 32A and the second portion 32B is, for example, rectangular in plan view.

The second metal layer 33 is formed on the lower surface (the surface facing in the z1 direction) of the insulating layer 31. The constituent material of the second metal layer 33 is the same as the constituent material of the first metal layer 32. In the example shown in FIG. 12, the lower surface (the bottom surface 302, described later) of the second metal layer 33 may be exposed from the sealing resin 8. The lower surface may not be exposed from the sealing resin 8 and may be covered with the sealing resin 8. The second metal layer 33 overlaps with both the first portion 32A and the second portion 32B in plan view.

As shown in FIGS. 13 to 20, the support substrate 3 has a support surface 301 and a bottom surface 302. The support surface 301 and the bottom surface 302 are spaced apart from each other in the z direction. The support surface 301 faces in the z2 direction, and the bottom surface 302 faces in the z1 direction. As shown in FIG. 12, the bottom surface 302 is exposed from the sealing resin 8. The support surface 301 is the upper surface of the first metal layer 32 and constituted of the upper surface of the first portion 32A and the upper surface of the second portion 32B. The support surface 301 faces the conductive substrate 2, and the conductive substrate 2 is bonded to the support surface 301. The bottom surface 302 is the lower surface of the second metal layer 33. A heat dissipation member (e.g., a heat sink, not shown) can be attached to the bottom surface 302. The dimension of the support substrate 3 in the z direction (the distance from the support surface 301 to the bottom surface 302 in the z direction) is, for example, 0.7 mm to 2.0 mm.

Each of the first terminal 41, the second terminal 42, the third terminals 43, and the fourth terminal 44 is provided by a plate made of a metal. The constituent material of the metal plate is, for example, Cu or a Cu alloy. In the example shown in FIGS. 1 to 5, 10 and 12, the semiconductor device A1 has one each of the first terminal 41, the second terminal 42 and the fourth terminal 44, and two third terminals 43.

The DC voltage to be converted is inputted to the first terminal 41, the second terminal 42 and the fourth terminal 44. The fourth terminal 44 is a positive electrode (P terminal), and each of the first terminal 41 and the second terminal 42 is a negative electrode (N terminal). The AC voltage converted by the first semiconductor elements 10A and the second semiconductor elements 10B is outputted from the third terminals 43. Each of the first terminal 41, the second terminal 42, the third terminals 43 and the fourth terminal 44 includes a portion covered with the sealing resin 8 and a portion exposed from the sealing resin 8.

As shown in FIG. 14, the fourth terminal 44 is formed integrally with the second conductive portion 2B. Unlike this configuration, the fourth terminal 44 may be provided separately from the second conductive portion 2B and conductively bonded to the second conductive portion 2B. As shown in FIG. 10, etc., the fourth terminal 44 is located on the x2 side with respect to the second semiconductor elements 10B and the second conductive portion 2B (the conductive substrate 2). The fourth terminal 44 is electrically connected to the second conductive portion 2B and also electrically connected to the reverse electrode 15 (the drain electrode) of each second semiconductor element 10B via the second conductive portion 2B.

As shown in FIG. 10, the first terminal 41 and the second terminal 42 are spaced apart from the second conductive portion 2B. As shown in FIGS. 5 and 8, the first conductive member 5 is bonded to the first terminal 41 and the second terminal 42. As shown in FIGS. 5, 10, etc., the first terminal 41 and the second terminal 42 are located on the x2 side with respect to the second semiconductor elements 10B and the second conductive portion 2B (the conductive substrate 2). The first terminal 41 and the second terminal 42 are electrically connected to the first conductive member 5 and also electrically connected to the second obverse electrode 12 (the source electrode) of each second semiconductor element 10B via the first conductive member 5.

As shown in FIGS. 1 to 5, 10, 12, etc., in the semiconductor device A1, the first terminal 41, the second terminal 42 and the fourth terminal 44 protrude from the sealing resin 8 in the x2 direction. The first terminal 41, the second terminal 42 and the fourth terminal 44 are spaced apart from each other. The first terminal 41 and the second terminal 42 are located opposite to each other with the fourth terminal 44 interposed therebetween in the y direction. The first terminal 41 is located on the y2 side of the fourth terminal 44, and the second terminal 42 is located on the y1 side of the fourth terminal 44. The first terminal 41, the second terminal 42 and the fourth terminal 44 overlap with each other as viewed in the y direction.

As will be understood from FIGS. 10 and 13, the two third terminals 43 are integrally formed with the first conductive portion 2A. Unlike this configuration, the third terminals 43 may be provided separately from the first conductive portion 2A and conductively bonded to the first conductive portion 2A. As shown in FIG. 10, etc., the two third terminals 43 are located on the x1 side with respect to the first semiconductor elements 10A and the first conductive portion 2A (the conductive substrate 2). Each third terminal 43 is electrically connected to the first conductive portion 2A and also electrically connected to the reverse electrode 15 (the drain electrode) of each first semiconductor element 10A via the first conductive portion 2A. Note that the number of third terminals 43 is not limited to two, and may be one, or three or more. When only one third terminal 43 is provided, the third terminal 43 is preferably connected to the middle part in the y direction of the first conductive portion 2A.

Each of the control terminals 45 is a pin-shaped terminal for controlling the first semiconductor elements 10A and the second semiconductor elements 10B. The control terminals 45 include a plurality of first control terminals 46A to 46E and a plurality of second control terminals 47A to 47E. The first control terminals 46A to 46E are used to control the first semiconductor elements 10A, for example. The second control terminals 47A to 47E are used to control the second semiconductor elements 10B, for example.

The first control terminals 46A to 46E are spaced apart from each other in the y direction. As shown in FIGS. 10, 14, etc., the first control terminals 46A to 46E are supported on the first conductive portion 2A via the control terminal support 48 (the first support portion 48A, described later). As shown in FIGS. 5 and 10, the first control terminals 46A to 46E are located between the first semiconductor elements 10A and the two third terminals 43 in the x direction.

The first control terminal 46A is a terminal (a gate terminal) for inputting a drive signal for the first semiconductor elements 10A. A drive signal for driving the first semiconductor elements 10A is inputted (e.g., a gate voltage is applied) to the first control terminal 46A.

The first control terminal 46B is a terminal (a source sense terminal) for detecting a source signal of the first semiconductor elements 10A. The voltage applied to the second obverse electrode 12 (the source electrode) of each first semiconductor element 10A (the voltage corresponding to the source current) is detected from the first control terminal 46B.

The first control terminal 46C and the first control terminal 46D are terminals electrically connected to a thermistor 17.

The first control terminal 46E is a terminal (a drain sense terminal) for detecting a drain signal of the first semiconductor elements 10A. The voltage applied to the reverse electrode 15 (the drain electrode) of each first semiconductor element 10A (the voltage corresponding to the drain current) is detected from the first control terminal 46E.

The second control terminals 47A to 47E are spaced apart from each other in the y direction. As shown in FIGS. 10, 14, etc., the second control terminals 47A to 47E are supported on the second conductive portion 2B via the control terminal support 48 (the second support portion 48B, described later). As shown in FIGS. 5 and 10, the second control terminals 47A to 47E are located between the second semiconductor elements 10B and the first, the second and the fourth terminals 41, 42 and 44 in the x direction.

The second control terminal 47A is a terminal (a gate terminal) for inputting a drive signal for the second semiconductor elements 10B. A drive signal for driving the second semiconductor elements 10B is inputted (e.g., a gate voltage is applied) to the second control terminal 47A. The second control terminal 47B is a terminal (a source sense terminal) for detecting a source signal of the second semiconductor elements 10B. The voltage applied to the second obverse electrode 12 (the source electrode) of each second semiconductor element 10B (the voltage corresponding to the source current) is detected from the second control terminal 47B. The second control terminal 47C and the second control terminal 47D are terminals electrically connected to a thermistor 17. The second control terminal 47E is a terminal (a drain sense terminal) for detecting a drain signal of the second semiconductor elements 10B. The voltage applied to the reverse electrode 15 (the drain electrode) of each second semiconductor element 10B (the voltage corresponding to the drain current) is detected from the second control terminal 47E.

Each of the control terminals 45 (the first control terminals 46A to 46E and the second control terminals 47A to 47E) includes a holder 451 and a metal pin 452.

The holders 451 are made of an electrically conductive material. As shown in FIGS. 15 and 16, the holders 451 are bonded to the control terminal support 48 (the first metal layer 482, described later) via a conductive bonding material 459. Each holder 451 includes a cylindrical portion, an upper flange portion, and a lower flange portion. The upper flange portion is connected to the upper part of the cylindrical portion, and the lower flange portion is connected to the lower part of the cylindrical portion. A metal pin 452 is inserted in at least the upper flange portion and the cylindrical portion of each holder 451. The holder 451 is covered with the sealing resin 8 (the second protrusion 852, described later).

The metal pins 452 are bar-shaped members extending in the z direction. The metal pins 452 are supported by being press-fitted into the holders 451. The metal pins 452 are electrically connected to the control terminal support 48 (the first metal layer 482, described below) at least via the holders 451. When the lower ends (the ends on the z1 side) of the metal pins 452 are in contact with the conductive bonding material 459 within the through-holes of the holders 451 as in the example shown in FIGS. 15 and 16, the metal pins 452 are electrically connected to the control terminal support 48 via the conductive bonding material 459.

The control terminal support 48 supports the plurality of control terminals 45. The control terminal support 48 is interposed between the obverse surface 201 (the conductive substrate 2) and the control terminals 45 in the z direction.

The control terminal support 48 includes a first support portion 48A and a second support portion 48B. The first support portion 48A is disposed on the first conductive portion 2A of the conductive substrate 2 and supports the first control terminals 46A to 46E of the control terminals 45. As shown in FIG. 15, the first support portion 48A is bonded to the first conductive portion 2A via a bonding material 49. The bonding material 49 may be electrically conductive or insulating, and solder may be used, for example. The second support portion 48B is disposed on the second conductive portion 2B of the conductive substrate 2 and supports the second control terminals 47A to 47D of the control terminals 45. As shown in FIG. 16, the second support portion 48B is bonded to the second conductive portion 2B via a bonding material 49.

The control terminal support 48 (each of the first support portion 48A and the second support portion 48B) is provided by a DBC substrate, for example. The control terminal support 48 includes an insulating layer 481, a first metal layer 482 and a second metal layer 483 laminated on top of each other.

The insulating layer 481 is made of ceramics, for example. The insulating layer 481 may be rectangular in plan view.

As shown in FIGS. 15, 16, etc., the first metal layer 482 is formed on the upper surface of the insulating layer 481. Each control terminal 45 stands on the first metal layer 482. The first metal layer 482 is Cu or a Cu alloy, for example. As shown in FIG. 10, etc., the first metal layer 482 includes a first portion 482A, a second portion 482B, a third portion 482C, a fourth portion 482D, and a fifth portion 482E. The first portion 482A, the second portion 482B, the third portion 482C, the fourth portion 482D and the fifth portion 482E are spaced apart and insulated from each other.

The first portion 482A, to which a plurality of wires 71 are bonded, is electrically connected to the first obverse electrodes 11 (gate electrodes) of the first semiconductor elements 10A (the second semiconductor elements 10B) via the wires 71. The first portion 482A and the sixth portion 482F are connected to each other via a plurality of wires 73. Thus, the sixth portion 482F is electrically connected to the first obverse electrodes 11 (gate electrodes) of the first semiconductor elements 10A (the second semiconductor elements 10B) via the wires 73 and the wires 71. As shown in FIG. 10, the first control terminal 46A is bonded to the sixth portion 482F of the first support portion 48A, and the second control terminal 47A is bonded to the sixth portion 482F of the second support portion 48B.

The second portion 482B, to which a plurality of wires 72 are bonded, is electrically connected to the second obverse electrodes 12 (source electrodes) of the first semiconductor elements 10A (the second semiconductor elements 10B) via the wires 72. As shown in FIG. 10, the first control terminal 46B is bonded to the second portion 482B of the first support portion 48A, and the second control terminal 47B is bonded to the second portion 482B of the second support portion 48B.

A thermistor 17 is bonded to the third portion 482C and the fourth portion 482D. As shown in FIG. 10, the first control terminals 46C and 46D are bonded to the third portion 482C and the fourth portion 482D, respectively, of the first support portion 48A. The second control terminals 47C and 47D are bonded to the third portion 482C and the fourth portion 482D, respectively, of the second support portion 48B.

The fifth portion 482E of the first support portion 48A, to which a wire 74 is bonded, is electrically connected to the first conductive portion 2A via the wire 74. The fifth portion 482E of the second support portion 48B, to which a wire 74 is bonded, is electrically connected to the second conductive portion 2B via the wire 74. As shown in FIG. 10, the first control terminal 46E is bonded to the fifth portion 482E of the first support portion 48A, and the second control terminal 47E is bonded to the fifth portion 482E of the second support portion 48B. Each of the wires 71 to 74 is, for example, a bonding wire. The constituent material of the wires 71 to 74 include one of Au (gold), Al or Cu, for example.

As shown in FIG. 15, 16, etc., the second metal layer 483 is formed on the lower surface of the insulating layer 481. As shown in FIG. 15, the second metal layer 483 of the first support portion 48A is bonded to the first conductive portion 2A via a bonding material 49. As shown in FIG. 16, the second metal layer 483 of the second support portion 48B is bonded to the second conductive portion 2B via a bonding material 49.

The first conductive member 5 and the second conductive member 6, together with the conductive substrate 2, constitute a path for the main circuit current switched by the first semiconductor elements 10A and the second semiconductor elements 10B. The first conductive member 5 and the second conductive member 6 are spaced apart from the obverse surface 201 (the conductive substrate 2) in the z2 direction and overlap with the obverse surface 201 in plan view. In the present embodiment, each of the first conductive member 5 and the second conductive member 6 is provided by a plate made of a metal. The metal is Cu or a Cu alloy, for example. Specifically, each of the first conductive member 5 and the second conductive member 6 is a metal plate bent as appropriate.

The first conductive member 5 is connected to the second obverse electrode 12 (the source electrode) of each first semiconductor element 10A and the first and the second terminals 41 and 42 to electrically connect the second obverse electrode 12 of each first semiconductor element 10A and the first and the second terminals 41 and 42 to each other. The first conductive member 5 constitutes a path for the main circuit current switched by the first semiconductor elements 10A. The first conductive member 5 has a maximum dimension in the x direction of 25 mm to 40 mm, for example, and a maximum dimension in the y direction of 30 mm to 45 mm, for example. As shown in FIGS. 8 and 9, the first conductive member 5 includes a first wiring portion 51, a second wiring portion 52, a third wiring portion 53, and a fourth wiring portion 54.

The first wiring portion 51 includes a first end 511, a second end 512, a first connecting part 513, a first part 514, and a second part 515. The first end 511 is connected to the first terminal 41. The first end 511 and the first terminal 41 are bonded together with a conductive bonding material 59. The first wiring portion 51 as a whole has a band shape extending in the x direction in plan view.

The second end 512 is spaced apart from the first end 511 in the x direction. As shown in FIGS. 8, 9, etc., the second end 512 is located on the x1 side with respect to the first end 511. The first connecting part 513 is located between the first end 511 and the second end 512. The first connecting part 513 is the part at which the second wiring portion 52 (the first band portion 521, described later) is connected to the first wiring portion 51.

The first part 514 is located between the first connecting part 513 and the first end 511 and connected to both of the first end 511 and the second part 515. The first part 514 overlaps with the second conductive portion 2B in plan view. The second part 515 is located between the first connecting part 513 and the second end 512 and connected to the second end 512. The second part 515 overlaps with both of the second conductive portion 2B and the first conductive portion 2A in plan view.

In the present embodiment, the first part 514 has a first main section 514A and a first extension 514B. The first main section 514A is located on the z2 side with respect to the obverse surface 201 (the conductive substrate 2). The first main section 514A overlaps with the second conductive portion 2B (the conductive substrate 2) in plan view. As shown in FIG. 20, etc., the first main section 514A is parallel to the obverse surface 201. As shown in FIGS. 5, 6, etc., the first main section 514A overlaps with the second part 515 as viewed in the x direction.

The first extension 514B is connected to the first main section 514A in the y2 direction. In the present embodiment, as shown in FIG. 6, the first extension 514B hangs out of the y2-side of the first main section 514A, having an arcuate shape. The first extension 514B is bent in the z1 direction with respect to the first main section 514A.

As shown in FIG. 8, the first extension 514B does not overlap with the second conductive portion 2B (the conductive substrate 2) in plan view. In the present embodiment, as shown in FIG. 6, the first extension 514B overlaps with the second conductive portion 2B (the conductive substrate 2) as viewed in the y direction.

As shown in FIGS. 5, 8, 20, etc., the first part 514 (the first main section 514A) has a first opening 514c. The first opening 514c is a portion partially cut away in plan view. In the present embodiment, the first opening 514c is located at a position that overlaps with the obverse surface 201 of the second conductive portion 2B (the conductive substrate 2) in plan view and does not overlap with the second semiconductor elements 10B in plan view. The first opening 514c is provided at a position offset toward the y2 side of the second conductive portion 2B (the conductive substrate 2) in plan view. In the present embodiment, the first opening 514c is an arcuate notch recessed in the y2 direction from the y1-side edge in the first main section 514A. The shape in plan view of the first opening 514c is not limited, and may be a notch as in the present embodiment, or a hole unlike the present embodiment.

As shown in FIGS. 5, 8, etc., the second part 515 has an opening 515a. In the present embodiment, the second part 515 has two openings 515a. The two openings 515a are spaced apart from each other in the x direction. The opening 515a on the x2 side is located at a position that overlaps with the obverse surface 201 of the second conductive portion 2B (the conductive substrate 2) in plan view and does not overlap with the second semiconductor elements 10B in plan view. The opening 515a on the x1 side is located at a position that overlaps with the obverse surface 201 of the first conductive portion 2A (the conductive substrate 2) in plan view and does not overlap with the first semiconductor elements 10A in plan view. Each opening 515a is provided at a position offset toward the y2 side of the second conductive portion 2B (the first conductive portion 2A) in plan view. In the present embodiment, each opening 515a is an arcuate notch recessed in the y2 direction from the y1-side edge in the second part 515. The shape in plan view of the opening 515a is not limited, and may be a notch as in the present embodiment, or a hole unlike the present embodiment.

As shown in FIG. 9, the first extension 514B is located at a position corresponding to the first opening 514c and overlaps with the first opening 514c as viewed in the y direction. The first part 514 (the first main section 514A and the first extension 514B) is curved to bulge in the y2 direction. As will be understood from FIGS. 9, 20, etc., the first dimension L1, which is the size of the first part 514 (the first main section 514A and the first extension 514B) in a direction orthogonal to the flow direction of the main circuit current, is larger than the second dimension L2, which is the size of the second part 515 in a direction orthogonal to the flow direction of the main circuit current. Herein, the direction orthogonal to the flow direction of the main circuit current in the first part 514 (the first main section 514A and the first extension 514B) is not limited to one particular direction, but includes a direction along the bent portion (the first extension 514B) (see FIG. 20) and a direction toward the curved portion (see FIG. 9).

The second wiring portion 52 has a first band portion 521 and a second band portion 522. The first band portion 521 has a band shape extending in the y direction in plan view. The first band portion 521 is connected to the first wiring portion 51 between the first end 511 and the second end 512. The first band portion 521 extends from the first connecting part 513 in the y1 direction. The first band portion 521 overlaps with the second semiconductor elements 10B in in plan view.

The second wiring portion 52 has at least one second band portion 522. In the present embodiment, the second wiring portion 52 has a plurality of (three) second band portions 522. Each of the second band portions 522 has a band shape extending in the x direction in plan view. The second band portions 522 are spaced apart from each other in the y direction and disposed parallel (or generally parallel) with each other. In plan view, each of the second band portions 522 is connected at one end thereof to the first band portion 521 at a location between two second semiconductor elements 10B that are adjacent to each other in the y direction, and extends in the x1 direction.

The third wiring portion 53 includes a third end 531, a fourth end 532, a second connecting part 533, a third part 534, and a fourth part 535. The third end 531 is connected to the second terminal 42. The third end 531 and the second terminal 42 are bonded together with a conductive bonding material 59. The third wiring portion 53 as a whole has a band shape extending in the x direction in plan view. The first wiring portion 51 and the third wiring portion 53 are spaced apart from each other in the y direction. The third wiring portion 53 is located on the y1 side with respect to the first wiring portion 51.

The fourth end 532 is spaced apart from the third end 531 in the x direction. As shown in FIGS. 8, 9, etc., the fourth end 532 is located on the x1 side with respect to the third end 531. The second connecting part 533 is located between the third end 531 and the fourth end 532. The second connecting part 533 is the part at which the second wiring portion 52 (the first band portion 521) is connected to the third wiring portion 53. The first band portion 521 is connected to the third wiring portion 53 between the first end 511 and the second end 512.

The third part 534 is located between the second connecting part 533 and the third end 531 and connected to both of the third end 531 and the fourth part 535. The third part 534 overlaps with the second conductive portion 2B in plan view. The fourth part 535 is located between the second connecting part 533 and the fourth end 532 and connected to the fourth end 532. The fourth part 535 overlaps with both of the second conductive portion 2B and the first conductive portion 2A in plan view.

In the present embodiment, the third part 534 has a second main section 534A and a second extension 534B. The second main section 534A is located on the z2 side with respect to the obverse surface 201 (the conductive substrate 2). The second main section 534A overlaps with the second conductive portion 2B (the conductive substrate 2) in plan view. As shown in FIG. 20, etc., the second main section 534A is parallel to the obverse surface 201. As shown in FIGS. 5, 7, etc., the second main section 534A overlaps with the fourth part 535 as viewed in the x direction.

The second extension 534B is connected to the second main section 534A in the y1 direction. In the present embodiment, as shown in FIG. 7, the second extension 534B hangs out of the y1-side of the second main section 534A, having an arcuate shape. The second extension 534B is bent in the z1 direction with respect to the second main section 534A.

As shown in FIG. 8, the second extension 534B does not overlap with the second conductive portion 2B (the conductive substrate 2) in plan view. In the present embodiment, as shown in FIG. 7, the second extension 534B overlaps with the second conductive portion 2B (the conductive substrate 2) as viewed in the y direction.

As shown in FIGS. 5, 8, 20, etc., the third part 534 (the second main section 534A) has a second opening 534c. The second opening 534c is a portion partially cut-away in plan view. In the present embodiment, the second opening 534c is located at a position that overlaps with the obverse surface 201 of the second conductive portion 2B (the conductive substrate 2) in plan view and does not overlap with the second semiconductor elements 10B in plan view. The second opening 534c is provided at a position offset toward the y1 side of the second conductive portion 2B (the conductive substrate 2) in plan view. In the present embodiment, the second opening 534c is an arcuate notch recessed in the y1 direction from the y2-side edge in the second main section 534A. The shape in plan view of the second opening 534c is not limited, and may be a notch as in the present embodiment, or a hole unlike the present embodiment.

As shown in FIGS. 5, 8, etc., the fourth part 535 has an opening 535a. In the present embodiment, the fourth part 535 has two openings 535a. The two openings 535a are spaced apart from each other in the x direction. The opening 535a on the x2 side is located at a position that overlaps with the obverse surface 201 of the second conductive portion 2B (the conductive substrate 2) in plan view and does not overlap with the second semiconductor elements 10B in plan view. The opening 535a on the x1 side is located at a position that overlaps with the obverse surface 201 of the first conductive portion 2A (the conductive substrate 2) in plan view and does not overlap with the first semiconductor elements 10A in plan view. Each opening 535a is provided at a position offset toward the y1 side of the second conductive portion 2B (the first conductive portion 2A) in plan view. In the present embodiment, the opening 535a is an arcuate notch recessed in the y1 direction from the y2-side edge in the fourth part 535. The shape in plan view of the opening 535a is not limited, and may be a notch as in the present embodiment, or a hole unlike the present embodiment.

As shown in FIG. 9, the second extension 534B is located at a position corresponding to the second opening 534c and overlaps with the second opening 534c as viewed in the y direction. The third part 534 (the second main section 534A and the second extension 534B) is curved to bulge in the y1 direction. As will be understood from FIGS. 9, 20, etc., the third dimension L3, which is the size of the third part 534 (the second main section 534A and the second extension 534B) in a direction orthogonal to the flow direction of the main circuit current, is larger than the fourth dimension L4, which is the size of the fourth part 535 in a direction orthogonal to the flow direction of the main circuit current. Herein, the direction orthogonal to the flow direction of the main circuit current in the third part 534 (the second main section 534A and the second extension 534B) is not limited to one particular direction, but includes a direction along the bent portion (the second extension 534B) (see FIG. 20) and a direction toward the curved portion (see FIG. 9).

In the present embodiment, as shown in FIG. 9, the first part 514 of the first wiring portion 51 and the third part 534 of the third wiring portion 53 overlap with the first band portion 521 of the second wiring portion 52 as viewed in the y direction.

The fourth wiring portion 54 is connected to both of the first wiring portion 51 (the second end 512) and the third wiring portion 53 (the fourth end 532). The fourth wiring portion 54 as a whole has a band shape extending in the y direction in plan view. As will be understood from FIG. 8, etc., the fourth wiring portion 54 overlaps with the first semiconductor elements 10A in plan view. As shown in FIG. 18, the fourth wiring portion 54 is connected to each of the first semiconductor elements 10A. The fourth wiring portion 54 has a plurality of dented regions 541. As shown in FIG. 18, each of the dented regions 541 protrudes in the z1 direction relative to other portions of the fourth wiring portion 54. In the present embodiment, each dented region 541 is formed with a slit 541a. In the present embodiment, as shown in FIGS. 8 and 18, the slit 541a is located in the middle part in the y direction of the dented region 541 and extends in the x direction. Each dented region 541 is made up of two portions separated in the y direction with the slit 541a between them. The dented regions 541 of the fourth wiring portion 54 are bonded to the first semiconductor elements 10A, respectively. Each dented region 541 of the fourth wiring portion 54 and the second obverse electrode 12 of a relevant first semiconductor element 10A are bonded to each other via a conductive bonding material 59. The constituent material of the conductive bonding material 59 is not particularly limited and may include solder, a metal paste or sintered metal, for example. The end on the x1 side of each second band portion 522 is connected between two dented regions 541 of the fourth wiring portion 54 that are adjacent to each other in the y direction.

The second conductive member 6 is connected to the second obverse electrode 12 (the source electrode) of each second semiconductor element 10B and the first conductive portion 2A to electrically connect the second obverse electrode 12 of each second semiconductor element 10B and the first conductive portion 2A to each other. The second conductive member 6 constitutes a path for the main circuit current switched by the second semiconductor elements 10B. As shown in FIGS. 8 and 10, the second conductive member 6 includes a main part 61, a plurality of first connecting ends 62 and a plurality of second connecting ends 63.

The main part 61 is located between the second semiconductor elements 10B and the first conductive portion 2A in the x direction and has a band shape extending in the y direction in plan view. As shown in FIG. 17, etc., the main part 61 is located on the z1 side with respect to the second wiring portion 52 (the second band portions 522) of the first conductive member 5 and located closer to the obverse surface 201 (the conductive substrate 2) than are the second band portions 522. The main part 61 overlaps with the second band portions 522 in plan view. In the present embodiment, as shown in FIGS. 8, 10, 14, etc., the main part 61 is formed with a plurality of openings 611. Each of the openings 611 is a through-hole penetrating in the z direction, for example. The openings 611 are aligned in the y2 direction in a mutually spaced manner. The openings 611 do not overlap with the second band portions 522 in plan view. The openings 611 are formed to facilitate the flow of the resin material between the upper side (z2 side) and the lower side (z1 side) at or near the main part 61 (the second conductive member 6) when the flowable resin material is injected to form the sealing resin 8. The configuration of the main part 61 (the second conductive member 6) is not limited to this configuration. For example, the openings 611 may not be formed.

The first connecting ends 62 and the second connecting ends 63 are connected to the main part 61 and disposed correspondingly to the second semiconductor elements 10B. As shown in FIGS. 14, 19, etc., each of the first connecting ends 62 is bonded to the second obverse electrode 12 of a relevant one of the second semiconductor elements 10B via a conductive bonding material 69, and each of the second connecting ends 63 is bonded to the first conductive portion 2A via a conductive bonding material 69. The constituent material of the conductive bonding material 69 is not particularly limited and may include solder, a metal paste or sintered metal, for example. In the present embodiment, each of the first connecting ends 62 is formed with an opening 621. Preferably, each opening 621 is formed to overlap with the middle part of a relevant second semiconductor element 10B in plan view. The openings 621 are through-holes penetrating in the z direction, for example. The openings 621 may be used to position the second conductive member 6 relative to the conductive substrate 2.

The sealing resin 8 covers the first semiconductor elements 10A, the second semiconductor elements 10B, the conductive substrate 2, the support substrate 3 (excluding the bottom surface 302), a part of each of the first terminal 41, the second terminal 42, the third terminals 43 and the fourth terminal 44, a part of each of the control terminals 45, the first conductive member 5, the second conductive member 6, and the wires 71 to 74. The sealing resin 8 is made of black epoxy resin, for example. The sealing resin 8 is made by molding, for example. The sealing resin 8 has dimensions of, for example, about 35 mm to 60 mm in the x direction, about 35 mm to 50 mm in the y direction, and about 4 mm to 15 mm in the z direction. These dimensions are the size of the largest portion along each direction. The sealing resin 8 has a resin obverse surface 81, a resin reverse surface 82, and a plurality of resin side surfaces 831 to 834.

As shown in FIGS. 11, 13, 18, etc., the resin obverse surface 81 and the resin reverse surface 82 are spaced apart from each other in the z direction. The resin obverse surface 81 faces in the z2 direction, and the resin reverse surface 82 faces in the z1 direction. The control terminals 45 (the first control terminals 46A to 46E and the second control terminals 47A to 47E) protrude from the resin obverse surface 81. As shown in FIG. 12, the resin reverse surface 82 has a frame shape surrounding the bottom surface 302 of the support substrate 3 (the lower surface of the second metal layer 33) in plan view. The bottom surface 302 of the support substrate 3 is exposed at the resin reverse surface 82 and may be flush with the resin reverse surface 82. Each of the resin side surfaces 831 to 834 is connected to the resin obverse surface 81 and the resin reverse surface 82 and sandwiched between these surfaces in the z direction. As shown in FIG. 4, etc., the resin side surface 831 and the resin side surface 832 are spaced apart from each other in the x direction. The resin side surface 831 faces in the x1 direction, and the resin side surface 832 faces in the x2 direction. The two third terminals 43 protrude from the resin side surface 831, and the first terminal 41, the second terminal 42 and the fourth terminal 44 protrude from the resin side surface 832. As shown in FIG. 4, etc., the resin side surface 833 and the resin side surface 834 are spaced apart from each other in the y direction. The resin side surface 833 faces in the y1 direction, and the resin side surface 834 faces in the y2 direction.

As shown in FIG. 4, the resin side surface 832 is formed with a plurality of recesses 832a. Each of the recesses 832a is a portion recessed in the x direction in plan view. One of the recesses 832a is formed between the first terminal 41 and the fourth terminal 44 in plan view, and another one of the recesses 832a is formed between the second terminal 42 and the fourth terminal 44 in plan view. The recesses 832a are provided to increase the distance along the resin side surface 832, or creepage distance between the first terminal 41 and the fourth terminal 44 and the distance along the resin side surface 832, or creepage distance between the second terminal 42 and the fourth terminal 44.

As shown in FIGS. 13, 14, etc., the sealing resin 8 has a plurality of first protrusions 851, a plurality of second protrusions 852, and resin void portions 86.

The first protrusions 851 protrude from the resin obverse surface 81 in the z direction. In plan view, the first protrusions 851 are disposed at four corners of the sealing resin 8. Each of the first protrusions 851 has a first-protrusion end surface 851a at its extremity (the end on the z2 side). The first-protrusion end surfaces 851a of the first protrusions 851 are parallel (or generally parallel) with the resin obverse surface 81 and located on the same plane (x-y plane). Each of the first protrusions 851 may have the shape of a hollow conical frustum with a bottom, for example. The first protrusions 851 are used as spacers when the semiconductor device A1 is mounted on a control circuit board or the like of a device configured to use the power produced by the semiconductor device A1. Each of the first protrusions 851 has a recess 851b and an inner wall surface 851c formed around the recess 851b. The shape of each first protrusion 851 may be columnar, and preferably cylindrical. The shape of the recess 851b may be cylindrical. Preferably, the inner wall surface 851c may be a single perfect circle in plan view.

The semiconductor device A1 may be mechanically fixed to a control circuit board or the like by screwing, for example. In such a case, female threads can be formed on the inner wall surfaces 851c of the recesses 851b of the first protrusions 851. Insert nuts may be embedded in the recesses 851b of the first protrusions 851.

As shown in FIG. 14, etc., the second protrusions 852 protrude from the resin obverse surface 81 in the z direction. The second protrusions 852 overlap with the control terminals 45 in plan view. The metal pins 452 of the control terminals 45 protrude from the second protrusions 852, respectively. Each of the second protrusions 852 may have the shape of a conical frustum, for example. Each of the second protrusions 852 covers the holder 451 and a part of the metal pin 452 of a control terminal 45.

As shown in FIGS. 13 and 20, the resin void portions 86 extend from the resin obverse surface 81 to the obverse surface 201 of the conductive substrate 2. Each resin void portion 86 is tapered, with its sectional area decreasing as proceeding in the z direction from the resin obverse surface 81 toward the obverse surface 201. The resin void portions 86 are formed during the molding of the sealing resin 8 and the area where the sealing resin 8 is not formed during the molding process.

Though illustration is omitted, the resin void portions 86 are formed, for example, because the flowable resin material could not flow into these areas as a result of these areas being occupied by pressing members during the molding process of the sealing resin 8. Such pressing members are used to apply pressing force to the obverse surface 201 of the conductive substrate 2 during the molding process and inserted into the first opening 514c, the openings 515a, the second opening 534c and the openings 535a of the first conductive member 5. In this way, the pressing members hold the conductive substrate 2 without interference with the first conductive member 5, and warpage of the support substrate 3, to which the conductive substrate 2 is bonded, is suppressed.

In the present embodiment, the semiconductor device A1 includes resin fill portions 88 as shown in FIGS. 13 and 20. The resin fill portions 88 are loaded into the resin void portions 86 to fill the resin void portions 86. The resin fill portions 88 may be made of epoxy resin as with the sealing resin 8, but may be made of a material different from the sealing resin 8.

The advantages of the present embodiment are described below.

The semiconductor device A1 includes the first semiconductor elements 10A, the conductive substrate 2, the first terminal 41, and the first conductive member 5. The first conductive member 5 constitutes a path for the main circuit current switched by the first semiconductor elements 10A and is connected to the first semiconductor elements 10A and the first terminal 41. The first conductive member 5 includes the first wiring portion 51 and the second wiring portion 52. The first wiring portion 51 has the first end 511 connected to the first terminal 41 and the second end 512 spaced apart from the first end 511 in the x direction. The second wiring portion 52 (the second band portion 522) is connected to the first wiring portion 51 between the first end 511 and the second end 512. The first wiring portion 51 has the first part 514 and the second part 515. The first part 514 is located between the first connecting part 513, to which the second wiring portion 52 (the second band portion 522) is connected, and the first end 511. The second part 515 is located between the first connecting part 513 and the second end 512.

The main circuit current flowing through the first conductive member 5 flows from the first semiconductor elements 10A toward the first terminal 41. In the present embodiment, the main circuit current in the first conductive member 5 is distributed between the second part 515 of the first wiring portion 51 and the second wiring portion 52 (the first band portion 521). The current flowing through the second part 515 and the current flowing through the second wiring portion 52 (the first band portion 521) merge at the first connecting part 513, and the merged current flows through the first part 514 toward the first terminal 41. The size of the first part 514 in a direction orthogonal to the flow direction of the main circuit current (the first dimension L1) is larger than the size of the second part 515 in a direction orthogonal to the flow direction of the main circuit current (the second dimension L2). With such a configuration, the cross-sectional area of the first part 514, through which the current after merging flows, is increased in comparison with the cross-sectional area of the second part 515, through which the current before merging flows, and an increase in current density in the first part 514 after merging is suppressed. Thus, when a large current flows in the semiconductor device A1 (the first semiconductor elements 10A), self-heating in the first part 514 after merging is suppressed. Thus, the semiconductor device A1 has a structure favorable for flowing a large current.

The second wiring portion 52 includes a first band portion 521 extending from the first connecting part 513 in the y1 direction. The first conductive member 5 includes the third wiring portion 53 located on the y1 side with respect to the first band portion 521. The second terminal 42 is disposed on the x2 side with respect to the conductive substrate 2. The third wiring portion 53 has the third end 531 connected to the second terminal 42 and the fourth end 532 spaced apart from the third end 531 in the x direction. The second band portion 522 is connected to the third wiring portion 53 between the third end 531 and the fourth end 532. The third wiring portion 53 has the third part 534 and the fourth part 535. The third part 534 is located between the second connecting part 533, to which the second band portion 522 is connected, and the third end 531. The fourth part 535 is located between the second connecting part 533 and the fourth end 532. The main circuit current in the first conductive member 5 is distributed among the second part 515 of the first wiring portion 51, the fourth part 535 of the third wiring portion 53, and the second wiring portion 52 (the first band portion 521). The current flowing through the fourth part 535 and the current flowing through the second wiring portion 52 (the first band portion 521) merge at the second connecting part 533, and the merged current flows through the third part 534 toward the second terminal 42. The size of the third part 534 in a direction orthogonal to the flow direction of the main circuit current (the third dimension L3) is larger than the size of the fourth part 535 in a direction orthogonal to the flow direction of the main circuit current (the fourth dimension L4). With such a configuration, the cross-sectional area of the third part 534, through which the current after merging flows, is increased in comparison with the cross-sectional area of the fourth part 535, through which the current before merging flows, and an increase in current density in the third part 534 after merging is suppressed. When a large current flows in the semiconductor device A1 (the first semiconductor elements 10A), the current can be distributed among a larger number of paths while self-heating after merging is suppressed in both the first part 514 and the third part 534. Thus, the semiconductor device A1 has a structure favorable for flowing a large current.

The first part 514 of the first wiring portion 51 has the first main section 514A and the first extension 514B. The first main section 514A is parallel to the obverse surface 201 and overlaps with the second part 515 as viewed in the x direction. The first extension 514B is connected to the first main section 514A in the y2 direction. The third part 534 of the third wiring portion 53 has the second main section 534A and the second extension 534B. The second main section 534A is parallel to the obverse surface 201 and overlaps with the fourth part 535 as viewed in the x direction. The second extension 534B is connected to the second main section 534A in the y1 direction. With such a configuration, the distance of the first part 514 (the first wiring portion 51) and the third part 534 (the third wiring portion 53) from the obverse surface 201 (the conductive substrate 2) is prevented from increasing. Therefore, the semiconductor device A1 can be made compact.

The first part 514 of the first wiring portion 51 and the third part 534 of the third wiring portion 53 overlap with the first band portion 521 of the second wiring portion 52 as viewed in the y direction. With such a configuration, the cross-sectional area of the current merging area can be appropriately increased near the first connecting part 513 of the first wiring portion 51 and near the second connecting part 533 of the third wiring portion 53. Thus, an increase in current density after merging of the current is reliably suppressed in both the first part 514 and the third part 534. The semiconductor device A1 having such a configuration is more favorable for flowing a large current.

The first extension 514B bends from the first main section 514A and extends in the z1 direction. The second extension 534B bends from the second main section 534A and extends in the z1 direction. With such a configuration, the dimensions in the z direction and the dimension in the y direction of the first conductive member 5 are not increased by the provision of the first extension 514B and the second extension 534B to increase the cross-sectional area of the first part 514 and the third part 534. The semiconductor device A1 having such a configuration is favorable for downsizing and for flowing a large current.

The first main section 514A and the second main section 534A overlap with the second conductive portion 2B (the conductive substrate 2) in plan view. The first extension 514B and the second extension 534B do not overlap with the second conductive portion 2B (the conductive substrate 2) in plan view, but overlap with the second conductive portion 2B (the conductive substrate 2) as viewed in the y direction. With such a configuration, it is possible to further increase the cross-sectional areas of the first part 514 (the first main section 514A and the first extension 514B) and the third part 534 (the second main section 534A and the second extension 534B) while making the semiconductor device A1 compact.

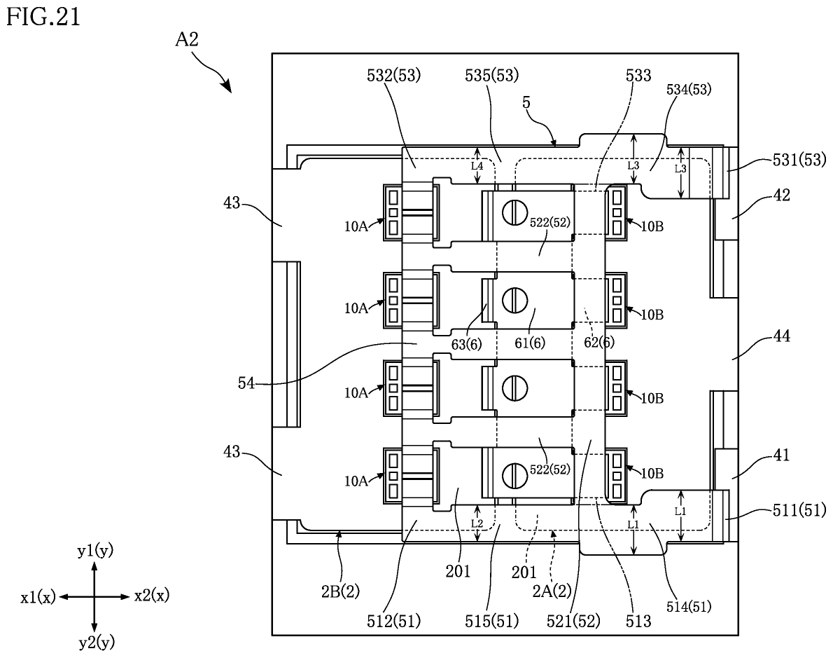

FIG. 21 shows a semiconductor device according to a first variation of the first embodiment. FIG. 21 is a plan view corresponding to FIG. 8 of the foregoing embodiment. In FIG. 21 and the subsequent figures, the elements that are identical or similar to those of the semiconductor device A1 of the foregoing embodiment are denoted by the same reference signs as those used for the foregoing embodiment, and the description thereof is omitted as appropriate.

The semiconductor device A2 of the present variation differs from the foregoing embodiment in configuration of the first conductive member 5, and mainly in configuration of the first part 514 (the first wiring portion 51) and the third part 534 (the third wiring portion 53). The first part 514 does not have the bent first extension 514B, and the third part 534 does not have the second extension 534B. Also, the first wiring portion 51 and the third wiring portion 53 do not have the first opening 514c, the opening 515a, the second opening 534c, and the opening 535a. The control terminals 45 are omitted.

In the semiconductor device A2, the main circuit current flowing through the first conductive member 5 flows from the first semiconductor elements 10A toward the first terminal 41. The main circuit current in the first conductive member 5 is distributed between the second part 515 of the first wiring portion 51 and the second wiring portion 52 (the first band portion 521). The current flowing through the second part 515 and the current flowing through the second wiring portion 52 (the first band portion 521) merge at the first connecting part 513, and the merged current flows through the first part 514 toward the first terminal 41. The size of the first part 514 in a direction orthogonal to the flow direction of the main circuit current (the first dimension L1) is larger than the size of the second part 515 in a direction orthogonal to the flow direction of the main circuit current (the second dimension L2). With such a configuration, the cross-sectional area of the first part 514, through which the current after merging flows, is increased in comparison with the cross-sectional area of the second part 515, through which the current before merging flows, and an increase in current density in the first part 514 after merging is suppressed. Thus, when a large current flows in the semiconductor device A2 (the first semiconductor devices 10A), self-heating in the first part 514 after merging is suppressed. Thus, the semiconductor device A2 has a structure favorable for flowing a large current. Furthermore, the semiconductor device A2 has the same effect as the semiconductor device A1 of the foregoing embodiment within the same configuration as the foregoing embodiment.

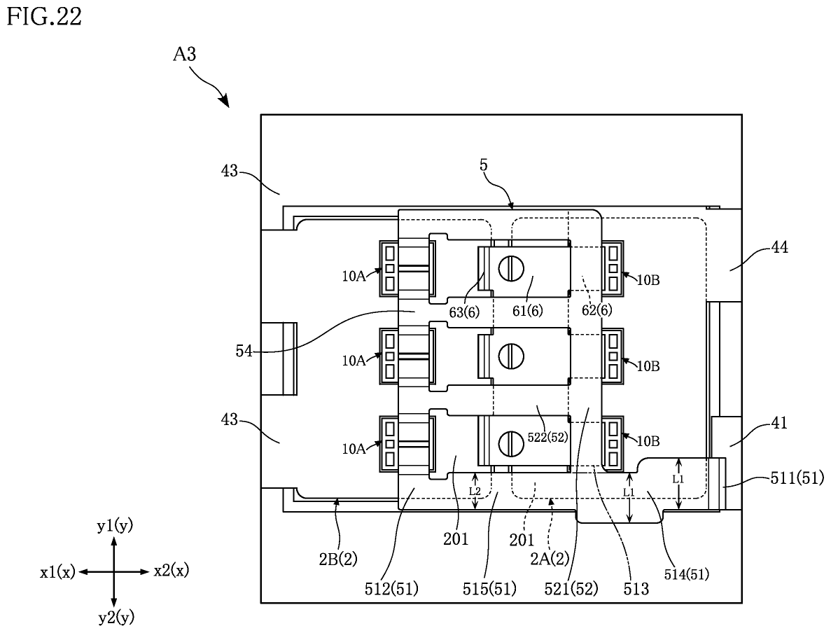

FIG. 22 shows a semiconductor device according to a second variation of the first embodiment. FIG. 22 is a plan view corresponding to FIG. 8 of the foregoing embodiment.

In the semiconductor device A3 of the present variation, the configuration of the first conductive member 5 differs significantly from the foregoing embodiment, and various changes have been made accordingly. Unlike the foregoing embodiment, the first conductive member 5 of the present variation does not have the third wiring portion 53. Also, the semiconductor device A3 does not include the second terminal 42 of the foregoing embodiment and includes three first semiconductor elements 10A and three second semiconductor elements 10B. The first wiring portion 51 does not have the first opening 514cc and the opening 515a. The control terminals 45 are omitted.

In the semiconductor device A3, the main circuit current flowing through the first conductive member 5 flows from the first semiconductor elements 10A toward the first terminal 41. The main circuit current in the first conductive member 5 is distributed between the second part 515 of the first wiring portion 51 and the second wiring portion 52 (the first band portion 521). The current flowing through the second part 515 and the current flowing through the second wiring portion 52 (the first band portion 521) merge at the first connecting part 513, and the merged current flows through the first part 514 toward the first terminal 41. The size of the first part 514 in a direction orthogonal to the flow direction of the main circuit current (the first dimension L1) is larger than the size of the second part 515 in a direction orthogonal to the flow direction of the main circuit current (the second dimension L2). With such a configuration, the cross-sectional area of the first part 514, through which the current after merging flows, is increased in comparison with the cross-sectional area of the second part 515, through which the current before merging flows, and an increase in current density in the first part 514 after merging is suppressed. Thus, when a large current flows in the semiconductor device A3 (the first semiconductor elements 10A), self-heating in the first part 514 after merging is suppressed. Thus, the semiconductor device A3 has a structure favorable for flowing a large current. Furthermore, the semiconductor device A3 has the same effect as the semiconductor device A1 of the foregoing embodiment within the same configuration as the foregoing embodiment.

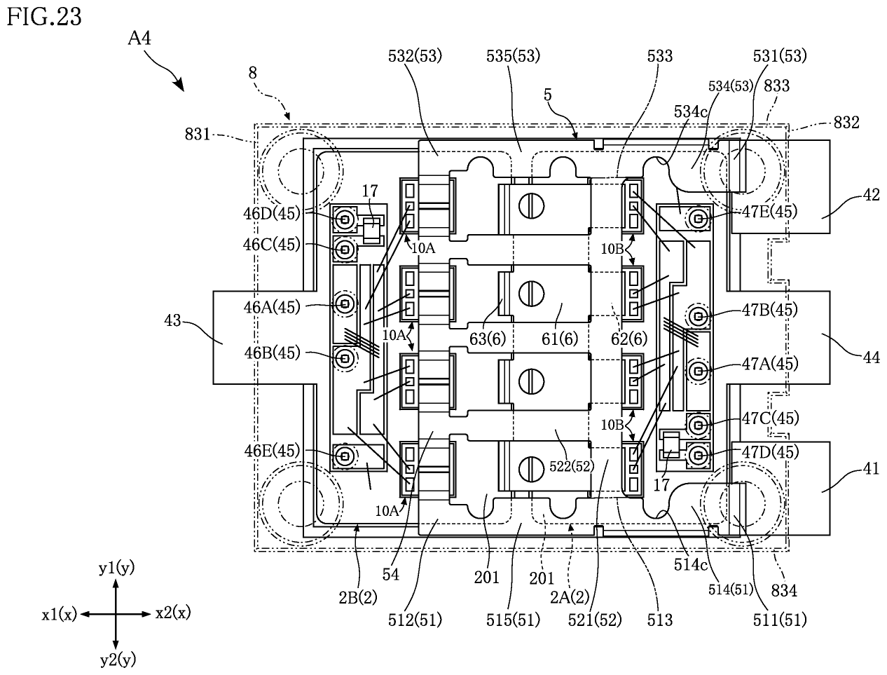

FIG. 23 shows a semiconductor device according to a third variation of the first embodiment. FIG. 23 is a plan view corresponding to FIG. 5 of the foregoing embodiment.

In the semiconductor device A4 of the present variation, only one third terminal 43 is provided. The third terminal 43 is connected to the middle part in the y direction of the first conductive portion 2A. The dimension in the y direction of the third terminal 43 in the present variation may be approximately the same as or may be larger than the dimension in the y direction of each third terminal 43 in the semiconductor device A1 of the foregoing embodiment. The configuration of the semiconductor device A4 is the same as that of the semiconductor device A1 except the third terminal 43.

In the semiconductor device A4, the main circuit current flowing through the first conductive member 5 flows from the first semiconductor elements 10A toward the first terminal 41. The main circuit current in the first conductive member 5 is distributed between the second part 515 of the first wiring portion 51 and the second wiring portion 52 (the first band portion 521). The current flowing through the second part 515 and the current flowing through the second wiring portion 52 (the first band portion 521) merge at the first connecting part 513, and the merged current flows through the first part 514 toward the first terminal 41. The size of the first part 514 in a direction orthogonal to the flow direction of the main circuit current (the first dimension L1) is larger than the size of the second part 515 in a direction orthogonal to the flow direction of the main circuit current (the second dimension L2). With such a configuration, the cross-sectional area of the first part 514, through which the current after merging flows, is increased in comparison with the cross-sectional area of the second part 515, through which the current before merging flows, and an increase in current density in the first part 514 after merging is suppressed. Thus, when a large current flows in the semiconductor device A4 (the first semiconductor elements 10A), self-heating in the first part 514 after merging is suppressed. Thus, the semiconductor device A4 has a structure favorable for flowing a large current. Other effects of the semiconductor device A1 of the foregoing embodiment are also achieved.

The semiconductor device according to the present disclosure is not limited to the foregoing embodiments. The specific configuration of each part of the semiconductor device according to the present disclosure can be varied in design in many ways.

The present disclosure includes the embodiments described in the following clauses.

Clause 1.

A semiconductor device comprising:
a conductive substrate including an obverse surface facing a first side in a thickness direction and a reverse surface facing away from the obverse surface;
a plurality of first semiconductor elements electrically bonded to the obverse surface and having a switching function;
a first terminal disposed on a first side in a first direction orthogonal to the thickness direction with respect to the conductive substrate; and
a first conductive member constituting a path for a main circuit current switched by the plurality of first semiconductor elements and connected to the plurality of first semiconductor elements and the first terminal, wherein
the first conductive member includes a first wiring portion and a second wiring portion,
the first wiring portion includes a first end connected to the first terminal and a second end spaced apart from the first end in the first direction,
the second wiring portion is connected to the first wiring portion between the first end and the second end,
the first wiring portion includes a first part located between a first connecting part at which the second wiring portion is connected to the first wiring portion and the first end, and a second part located between the first connecting part and the second end, and
a first dimension that is a size of the first part in a direction orthogonal to a flow direction of the main circuit current is larger than a second dimension that is a size of the second part in a direction orthogonal to the flow direction of the main circuit current.

Clause 2.

The semiconductor device according to clause 1, wherein the first conductive member comprises a plate made of a metal,
the first wiring portion extends in the first direction, and
the second wiring portion includes a first band portion extending from the first connecting part in a second direction orthogonal to the thickness direction and the first direction.

Clause 3.

The semiconductor device according to clause 2, further comprising a second terminal, wherein
the first wiring portion is located on a first side in the second direction with respect to the first band portion,
the first conductive member includes a third wiring portion located on a second side in the second direction with respect to the first band portion and extending in the first direction,
the second terminal is disposed on the first side in the first direction with respect to the conductive substrate, the third wiring portion being connected to the second terminal,
the third wiring portion includes a third end connected to the second terminal and a fourth end spaced apart from the third end in the first direction,
the first band portion is connected to the third wiring portion between the third end and the fourth end,
the third wiring portion includes a third part located between a second connecting part and the third end and a fourth part located between the second connecting part and the fourth end, the second connecting part being a part at which the first band portion is connected to the third wiring portion, and
a third dimension that is a size of the third part in a direction orthogonal to a flow direction of the main circuit current is larger than a fourth dimension that is a size of the fourth part in a direction orthogonal to the flow direction of the main circuit current.

Clause 4.

The semiconductor device according to clause 3, wherein the second wiring portion includes at least one second band portion connected to the first band portion and extending from the first band portion toward a second side in the first direction.

Clause 5.

The semiconductor device according to clause 4, wherein the first part includes a first main section located on a first side in the thickness direction with respect to the obverse surface and a first extension connected to the first main section on the first side in the second direction,
the first main section is parallel to the obverse surface and overlaps with the second part as viewed in the first direction,
the third part includes a second main section located on the first side in the thickness direction with respect to the obverse surface and a second extension connected to the second main section on the second side in the second direction, and
the second main section is parallel to the obverse surface and overlaps with the fourth part as viewed in the first direction.

Clause 6.

The semiconductor device according to clause 5, wherein the first part and the third part overlap with the first band portion as viewed in the second direction.

Clause 7.

The semiconductor device according to clause 5 or 6, wherein the first extension bends from the first main section and extends toward a second side in the thickness direction, and
the second extension bends from the second main section and extends toward the second side in the thickness direction.

Clause 8.

The semiconductor device according to clause 7, wherein the first main section and the second main section overlap with the conductive substrate as viewed in the thickness direction, and
the first extension and the second extension do not overlap with the conductive substrate as viewed in the thickness direction.

Clause 9.

The semiconductor device according to clause 8, wherein the first extension and the second extension overlap with the conductive substrate as viewed in the second direction.

Clause 10.

The semiconductor device according to clause 8 or 9, further comprising:
a support substrate which includes a support surface facing the first side in the thickness direction and to which the conductive substrate is bonded such that the reverse surface faces the support surface; and
a sealing resin including a resin obverse surface facing a same side as the obverse surface and a resin reverse surface facing away from the resin obverse surface, the sealing resin covering at least a part of the support substrate, at least a part of the conductive substrate, the plurality of first semiconductor elements, and the first conductive member, wherein
the first main section includes a first opening located on the second side in the second direction with respect to the first extension as viewed in the thickness direction, and
the second main section includes a second opening located on the first side in the second direction with respect to the second extension as viewed in the thickness direction.

Clause 11.

The semiconductor device according to clause 10, wherein the first opening is an arcuate notch recessed in the first main section from an end on the second side in the second direction toward the first side in the second direction,
the first extension hangs out of the first side in the second direction of the first main section to have an arcuate shape,
the second opening is an arcuate notch recessed in the second main section from an end on the first side in the second direction toward the second side in the second direction, and
the second extension hangs out of the second side in the second direction of the second main section to have an arcuate shape.

Clause 12.

The semiconductor device according to any one of clauses 4 to 11, wherein the plurality of first semiconductor elements are spaced apart from each other in the second direction,
the first conductive member includes a fourth wiring portion connected to the second end and the fourth end and extending in the second direction,
the fourth wiring portion is connected to the plurality of first semiconductor elements, and
an end on the second side in the first direction of the second band portion is connected to the fourth wiring portion.

Clause 13.

The semiconductor device according to clause 12, wherein the conductive substrate includes a first conductive portion and a second conductive portion disposed on the second side and on the first side, respectively, in the first direction in a mutually spaced manner,
the plurality of first semiconductor elements are electrically bonded to the first conductive portion, and
the semiconductor device further includes: a third terminal connected to the first conductive portion;
a plurality of second semiconductor elements electrically bonded to the second conductive portion and having a switching function;
a second conductive member connected to the plurality of second semiconductor elements and the first conductive portion and comprising a plate made of a metal; and
a fourth terminal connected to the second conductive portion.

Clause 14.

The semiconductor device according to clause 13, wherein the second conductive member overlaps with the second band portion as viewed in the thickness direction.

Clause 15.

The semiconductor device according to clause 14, wherein the plurality of second semiconductor element are spaced apart from each other in the second direction, and
the plurality of first semiconductor elements and the plurality of second semiconductor elements overlap with each other as viewed in the first direction.

### REFERENCE NUMERALS

A1, A2, A3, A4: Semiconductor device
10A: First semiconductor element
10B: Second semiconductor element
101: Element obverse surface
102: Element reverse surface 11: First obverse electrode
12: Second obverse electrode 13: Third obverse electrode
15: Reverse electrode 17: Thermistor
19: Conductive bonding material 2: Conductive substrate
2A: First conductive portion 2B: Second conductive portion
201: Obverse surface 202: Reverse surface
29: Conductive bonding material
3: Support substrate 301: Support surface
302: Bottom surface
31: Insulating layer 32: First metal layer
32A: First portion
32B: Second portion 321: First bonding layer
33: Second metal layer
41: First terminal 42: Second terminal 43: Third terminal
44: Fourth terminal 45: Control terminal 451: Holder
452: Metal pin 459: Conductive bonding material
46A, 46B, 46C, 46D, 46E: First control terminal
47A, 47B, 47C, 47D, 47E: Second control terminal
48: Control terminal support 481: Insulating layer
482: First metal layer
482A: First portion 482B: Second portion
482C: Third portion 482D: Fourth portion
482E: Fifth portion 482F: Sixth portion
483: Second metal layer 49: Bonding material
5: First conductive member 51: First wiring portion
511: First end 512: Second end
513: First connecting part 514: First part
514A: First main section 514B: First extension
514c: First opening 515: Second part 515a: Opening
52: Second wiring portion 521: First band portion
522: Second band portion 53: Third wiring portion
531: Third end 532: Fourth end
533: Second connecting part 534: Third part
534A: Second main section 534B: Second extension
534c: Second opening 535: Fourth part 535a: Opening
54: Fourth wiring portion 541: Dented region 541a: Slit
59: Conductive bonding material 6: Second conductive member
61: Main part
611: Opening 62: First connecting end 621: Opening
63: Second connecting end 69: Conductive bonding material
71, 72, 73, 74: Wire 8: Sealing resin
81: Resin obverse surface 82: Resin reverse surface
831, 832: Resin side surface 832a: Recess
833, 834: Resin side surface 851: First protrusion
851a: First-protrusion end surface 851b: Recess
851c: Inner wall surface 852: Second protrusion
86: Resin void portion
88: Resin fill portion L1: First dimension
L2: Second dimension
L3: Third dimension L4: Fourth dimension

1. A semiconductor device comprising:
a conductive substrate including an obverse surface facing a first side in a thickness direction and a reverse surface facing away from the obverse surface;
a plurality of first semiconductor elements electrically bonded to the obverse surface and having a switching function;
a first terminal disposed on a first side in a first direction orthogonal to the thickness direction with respect to the conductive substrate; and
a first conductive member constituting a path for a main circuit current switched by the plurality of first semiconductor elements and connected to the plurality of first semiconductor elements and the first terminal, wherein
the first conductive member includes a first wiring portion and a second wiring portion,
the first wiring portion includes a first end connected to the first terminal and a second end spaced apart from the first end in the first direction,
the second wiring portion is connected to the first wiring portion between the first end and the second end,
the first wiring portion includes a first part located between a first connecting part at which the second wiring portion is connected to the first wiring portion and the first end, and a second part located between the first connecting part and the second end, and
a first dimension that is a size of the first part in a direction orthogonal to a flow direction of the main circuit current is larger than a second dimension that is a size of the second part in a direction orthogonal to the flow direction of the main circuit current.

2. The semiconductor device according to claim 1, wherein the first conductive member comprises a plate made of a metal,
the first wiring portion extends in the first direction, and
the second wiring portion includes a first band portion extending from the first connecting part in a second direction orthogonal to the thickness direction and the first direction.

3. The semiconductor device according to claim 2, further comprising a second terminal, wherein
the first wiring portion is located on a first side in the second direction with respect to the first band portion,
the first conductive member includes a third wiring portion located on a second side in the second direction with respect to the first band portion and extending in the first direction,
the second terminal is disposed on the first side in the first direction with respect to the conductive substrate, the third wiring portion being connected to the second terminal,
the third wiring portion includes a third end connected to the second terminal and a fourth end spaced apart from the third end in the first direction,
the first band portion is connected to the third wiring portion between the third end and the fourth end,
the third wiring portion includes a third part located between a second connecting part and the third end and a fourth part located between the second connecting part and the fourth end, the second connecting part being a part at which the first band portion is connected to the third wiring portion, and
a third dimension that is a size of the third part in a direction orthogonal to a flow direction of the main circuit current is larger than a fourth dimension that is a size of the fourth part in a direction orthogonal to the flow direction of the main circuit current.

4. The semiconductor device according to claim 3, wherein the second wiring portion includes at least one second band portion connected to the first band portion and extending from the first band portion toward a second side in the first direction.

5. The semiconductor device according to claim 4, wherein the first part includes a first main section located on a first side in the thickness direction with respect to the obverse surface and a first extension connected to the first main section on the first side in the second direction,
the first main section is parallel to the obverse surface and overlaps with the second part as viewed in the first direction,
the third part includes a second main section located on the first side in the thickness direction with respect to the obverse surface and a second extension connected to the second main section on the second side in the second direction, and
the second main section is parallel to the obverse surface and overlaps with the fourth part as viewed in the first direction.

6. The semiconductor device according to claim 5, wherein the first part and the third part overlap with the first band portion as viewed in the second direction.

7. The semiconductor device according to claim 5, wherein the first extension bends from the first main section and extends toward a second side in the thickness direction, and
the second extension bends from the second main section and extends toward the second side in the thickness direction.

8. The semiconductor device according to claim 7, wherein the first main section and the second main section overlap with the conductive substrate as viewed in the thickness direction, and
the first extension and the second extension do not overlap with the conductive substrate as viewed in the thickness direction.

9. The semiconductor device according to claim 8, wherein the first extension and the second extension overlap with the conductive substrate as viewed in the second direction.

10. The semiconductor device according to claim 8, further comprising:
a support substrate which includes a support surface facing the first side in the thickness direction and to which the conductive substrate is bonded such that the reverse surface faces the support surface; and
a sealing resin including a resin obverse surface facing a same side as the obverse surface and a resin reverse surface facing away from the resin obverse surface, the sealing resin covering at least a part of the support substrate, at least a part of the conductive substrate, the plurality of first semiconductor elements, and the first conductive member, wherein
the first main section includes a first opening located on the second side in the second direction with respect to the first extension as viewed in the thickness direction, and
the second main section includes a second opening located on the first side in the second direction with respect to the second extension as viewed in the thickness direction.

11. The semiconductor device according to claim 10, wherein the first opening is an arcuate notch recessed in the first main section from an end on the second side in the second direction toward the first side in the second direction,
the first extension hangs out of the first side in the second direction of the first main section to have an arcuate shape,
the second opening is an arcuate notch recessed in the second main section from an end on the first side in the second direction toward the second side in the second direction, and
the second extension hangs out of the second side in the second direction of the second main section to have an arcuate shape.

12. The semiconductor device according to claim 4, wherein the plurality of first semiconductor elements are spaced apart from each other in the second direction,
the first conductive member includes a fourth wiring portion connected to the second end and the fourth end and extending in the second direction,
the fourth wiring portion is connected to the plurality of first semiconductor elements, and
an end on the second side in the first direction of the second band portion is connected to the fourth wiring portion.

13. The semiconductor device according to claim 12, wherein the conductive substrate includes a first conductive portion and a second conductive portion disposed on the second side and on the first side, respectively, in the first direction in a mutually spaced manner,
the plurality of first semiconductor elements are electrically bonded to the first conductive portion, and
the semiconductor device further includes: a third terminal connected to the first conductive portion;
a plurality of second semiconductor elements electrically bonded to the second conductive portion and having a switching function;
a second conductive member connected to the plurality of second semiconductor elements and the first conductive portion and comprising a plate made of a metal; and
a fourth terminal connected to the second conductive portion.

14. The semiconductor device according to claim 13, wherein the second conductive member overlaps with the second band portion as viewed in the thickness direction.

15. The semiconductor device according to claim 14, wherein the plurality of second semiconductor element are spaced apart from each other in the second direction, and
the plurality of first semiconductor elements and the plurality of second semiconductor elements overlap with each other as viewed in the first direction.
